(19) United States
(12) Patent Application Publication
(10) Pub. No.: US 2012/0052203 A1
(43) Pub. Date: Mar. 1, 2012

(54) SUBSTRATE PROCESSING APPARATUS AND METHOD OF PROCESSING SUBSTRATE

(75) Inventors: Tomoyasu Miyashita, Toyama (JP); Kenichi Suzaki, Toyama (JP)

(73) Assignee: HITACHI KOKUSAI ELECTRIC INC., Tokyo (JP)

(21) Appl. No.: 13/198,470

(22) Filed: Aug. 4, 2011

(30) Foreign Application Priority Data
Aug. 27, 2010 (JP) 2010-190339

(51) Int. Cl. C23C 16/455; C23C 16/52

(52) U.S. Cl. 427/248.1; 118/715

(57) ABSTRACT

Provided is a substrate processing apparatus and a substrate processing method, capable of preventing a reactive product from being deposited to the inside of a processing chamber and an exhaust line, and preventing the corrosion caused by hydrogen chloride gas. The method includes (a) forming a film on a substrate in a processing chamber; and (b) introducing an air from an outside of the processing chamber into an inside of the processing chamber, reacting an adherent adhered to the inside of the processing chamber and an inside of an exhaust line connected to the processing chamber with a moisture contained in the air to generate at least a hydrogen chloride gas, and exhausting the hydrogen chloride gas through the exhaust line, wherein the step (b) is performed after performing the step (a) and the step (b) is performed until a concentration level of the hydrogen chloride gas in the processing chamber is equal to or lower than a preset concentration level.

### CROSS-REFERENCE TO RELATED PATENT APPLICATION

This U.S. non-provisional patent application claims priority under 35 U.S.C. §119 of Japanese Patent Application No. 2010-190339, filed on Aug. 27, 2010 in the Japanese Patent Office, the entire contents of which are hereby incorporated by reference.

### BACKGROUND OF THE INVENTION

1. Field of the Invention

The present invention relates to a substrate processing apparatus and substrate processing technology, and more particularly to technology available for application to a substrate processing apparatus and substrate processing technology that form a film on a substrate using a source gas containing a compound having a chlorine (Cl) atom in a chemical formula.

2. Description of the Related Art

Japanese Unexamined Patent Application Publication No. 2006-59938 (Patent Document 1) discloses a substrate processing apparatus that forms films on a semiconductor substrate using a Si-based source gas such as SiH₄, Si₂H₆, SiH₂Cl₂, SiHCl₃, Si₂Cl₄, or the like, wherein the source gas is subjected to polymerization along with pyrolysis, and a by-product such as a-Si (SiₓH_{y}) or a chlorosilane polymer (SiₓCl_{y}, or SiₓH_{y}Cl_{z}) is deposited on a low-temperature gas exhaust pipe. Further, depending on a type of by-product, the by-product reacts with atmospheric moisture, which enters forcibly during the maintenance of the substrate processing apparatus, and causes hydrolysis, so that a high-combustible hydrolysate is produced.

Japanese Unexamined Patent Application Publication No. 2005-340283 (Patent Document 2) discloses that, in order to maintain a gas exhaust pipe installed on a substrate processing apparatus, a valve installed in a maintenance port is opened to supply air into the gas exhaust pipe before the gas exhaust pipe is separated, and a by-product (e.g. a chlorosilane polymer) adhered to the gas exhaust pipe is caused to react with moisture in the air to produce hydrogen chloride (HCl) gas. Furthermore, since the produced HCl gas is exhausted by a vacuum pump, the HCl gas can be prevented from being discharged into the air.

Japanese Unexamined Patent Application Publication No. 2000-106347 (Patent Document 3) discloses that a gas in a reaction tube is smoothly exhausted with a pressure difference of approximately −5 mmH₂O to approximately −70 mmH₂O relative to the atmospheric pressure when a semiconductor substrate is loaded and unloaded. Thereby, it is possible to prevent either a gas sublimated from the by-product or particles caused by the sublimated gas from hindering a film from being formed on the semiconductor substrate due to adsorption to the semiconductor substrate.

### RELATED ART DOCUMENT

### Patent Document

[Patent Document 1] Japanese Unexamined Patent Application Publication No. 2006-59938
[Patent Document 2] Japanese Unexamined Patent Application Publication No. 2005-340283
[Patent Document 3] Japanese Unexamined Patent Application Publication No. 2000-106347

### SUMMARY OF THE INVENTION

The substrate processing apparatus for forming a film on a substrate has been widely used in the process of processing the substrate. The substrate processing apparatus forms the film on the substrate, for instance, by heating the substrate disposed in a processing chamber thereof and introducing a source gas into the processing chamber. As one example, the process of forming the film on the substrate is performed using a compound having a chlorine (Cl) atom in a chemical formula as the source gas. In the substrate processing apparatus performing the film-forming process, the source gas is subjected to pyrolysis and polymerization, and a by-product such as a chlorosilane polymer is produced. The produced by-product is adhered to and deposited on an inside of the processing chamber or the inner wall of an exhaust line.

Typically, in the substrate processing apparatus, a processing chamber and a convey chamber are provided, and a holder that holds a plurality of semiconductor substrates is loaded from the convey chamber into the processing chamber, so that the film forming is performed on the semiconductor substrates. After the film forming is completed, the holder that holds the plurality of semiconductor substrates is unloaded from the processing chamber to the convey chamber. In the loading or unloading process, since a furnace port provided in the processing chamber is opened to load or unload the holder, the air is mixed from the convey chamber into the processing chamber via the open furnace port. Further, since the aforementioned by-product is deposited on the inner wall of the exhaust line connected with the processing chamber, it is necessary to perform maintenance on the exhaust line. During the maintenance of the exhaust line, an inside of the exhaust line is exposed to the air.

Thus, the by-product adhered to the inside of the processing chamber or the inner wall of the exhaust line is brought into contact with the air when the holder is loaded or unloaded between the convey chamber and the processing chamber or when the exhaust line undergoes maintenance. When the by-product is brought into contact with the air in this way, the by-product is gradually hydrolyzed by the moisture (H₂O) in the air, and is changed into a high-combustible hydrolysate. Further, hydrogen chloride gas is generated by the hydrolysis. For this reason, there is a risk of the high-combustible hydrolysate being abruptly burnt by impact or static electricity during the maintenance. Further, there is a risk of the hydrogen chloride gas produced by the hydrolysis corroding the inside of the processing chamber or the furnace port itself, and leaking from the furnace port to the convey to corrode the convey chamber.

Therefore, it is an objective of the present invention to provide a substrate processing apparatus and a substrate processing method, capable of preventing deposition of a reactive product to the inside of a processing chamber and an exhaust line, increasing maintainability or safety, and preventing the corrosion of the surroundings of the processing chamber.

The above and other objectives and new features of the present invention will become apparent from the following description and accompanying drawings.

Among the inventions disclosed herein, a configuration of the typical invention will be briefly described as follows.

According to an aspect of the present invention, there is provided a substrate processing method including (a) forming a film on a substrate in a processing chamber; and (b) introducing an air from an outside of the processing chamber into an inside of the processing chamber, reacting an adherent adhered to the inside of the processing chamber and an inside of an exhaust line connected to the processing chamber with a moisture contained in the air to generate at least a hydrogen chloride gas, and exhausting the hydrogen chloride gas through the exhaust line, wherein the step (b) is performed after performing the step (a) and the step (b) is performed until a concentration level of the hydrogen chloride gas in the processing chamber is equal to or lower than a preset concentration level.

### BRIEF DESCRIPTION OF THE DRAWINGS

FIG. 1 is a diagram illustrating a schematic configuration of a substrate processing apparatus according to a first embodiment of the present invention.

FIG. 2 is a top plan view illustrating a state where a wafer is charged into a susceptor.

FIG. 3 is a cross-sectional view taken along line A-A of FIG. 2.

FIG. 4 is a cross-sectional view illustrating how to separate the wafer from the susceptor.

FIG. 5 is a schematic configuration of a processing furnace of the substrate processing apparatus and a configuration of the surroundings of the processing furnace in the first embodiment.

FIG. 6 is a diagram illustrating a sequence of processes of manufacturing a semiconductor device.

FIG. 7 is a diagram illustrating a chemical reaction formula in which SiH₂Cl₂ (dichlorosilane), a source gas, is pyrolyzed and polymerized, and a by-product such as a chlorosilane polymer is produced.

FIG. 8 is a diagram illustrating a chemical reaction formula in which the chlorosilane polymer is subjected to a hydrolytic reaction with moisture, and a high-combustible hydrolysate and hydrogen chloride gas are produced.

FIG. 9 is a diagram illustrating a schematic configuration of the processing chamber of the substrate processing apparatus in the first embodiment.

FIG. 10 is a diagram illustrating a characteristic process performed in a boat unloading process in the first embodiment.

FIG. 11 is a diagram illustrating a state where, after the characteristic process is performed, the unloading of a boat is completed in the first embodiment.

FIG. 12 is a diagram illustrating the characteristic process performed in a standby process in a second embodiment.

FIG. 13 is a diagram illustrating the characteristic process performed in a boat loading process in the second embodiment.

FIG. 14 is a diagram illustrating a state where, after the characteristic process is performed, the loading of a boat is completed in the second embodiment.

FIG. 15 is a diagram illustrating the characteristic process performed in the boat unloading process in a third embodiment.

FIG. 16 is a diagram illustrating the characteristic process performed in the boat unloading process in the third embodiment.

FIG. 17 is a diagram illustrating the characteristic process performed in the standby process in the third embodiment.

FIG. 18 is a diagram illustrating the characteristic process performed in the boat loading process in the third embodiment.

FIG. 19 is a diagram illustrating the characteristic process performed in the boat unloading process in a fourth embodiment.

FIG. 20 is a graph showing a change in concentration level of hydrogen chloride gas (HCl concentration level) generated from the inside of the processing chamber over time.

FIG. 21 is a diagram illustrating the characteristic process performed in the boat unloading process in the fourth embodiment.

FIG. 22 is a diagram illustrating the characteristic process performed in the standby process in the fourth embodiment.

FIG. 23 is a diagram illustrating the characteristic process performed in the boat loading process in the fourth embodiment.

FIG. 24 is a diagram illustrating the characteristic process performed in the boat unloading process in a fifth embodiment.

FIG. 25 is a diagram illustrating the characteristic process performed in the boat unloading process in the fifth embodiment.

FIG. 26 is a diagram illustrating the characteristic process performed in the boat unloading process in a sixth embodiment.

FIG. 27 is a diagram illustrating the characteristic process performed in the boat unloading process in the sixth embodiment.

FIG. 28 is a diagram illustrating the characteristic process performed in the standby process in the sixth embodiment.

FIG. 29 is a diagram illustrating the characteristic process performed in the boat loading process in the sixth embodiment.

### DETAILED DESCRIPTION OF THE PREFERRED EMBODIMENTS

In the following embodiments, description will be made by being divided into a plurality of sections or embodiments, whenever necessary for convenience. Therefore, the sections or embodiments are not irrelevant to one another unless clearly specified otherwise, and any one thereof has a relation of modifications, details and supplementary explanations to some or all of the other.

Further, when reference is made to the number of elements or the like (including the number of pieces, numerical values, quantities, ranges, etc.) in the description of the following embodiments, the number thereof is not limited to a specific number and may be greater than, less than or equal to the specific number, unless clearly specified otherwise and definitely limited to the specific number in principle.

It is also needless to say that, in the following embodiments, the components (including steps, etc.) are not always essential unless clearly specified otherwise and considered to be definitely essential in principle.

Similarly, when reference is made to the shapes, positional relations, etc. of the components or the like in the following embodiments, they will include ones substantially analogous or similar to their shapes or the like unless clearly specified otherwise, considered not to be definite in principle, and the like. This is similarly applied to the above-described numerical values and ranges as well.

In all the drawings for explaining the embodiments, the same elements are indicated by the same reference numerals in principle, and so repetitive description thereof will be omitted. Further, some hatching may be provided to make it easy to read the drawings.

### First Embodiment

In the embodiments for carrying out the present invention, a substrate processing apparatus is configured, as one example, as a semiconductor manufacturing apparatus that performs various processing processes included in a method of manufacturing a substrate, a method of manufacturing a semiconductor device (e.g. an integrated circuit (IC), etc.), or a method of manufacturing a solar cell. The following description will be made about a case where the technical idea of the present invention is applied to a vertical substrate processing apparatus that forms a film on a semiconductor substrate (or a semiconductor wafer) using an epitaxial growth method, forms a film on a semiconductor substrate (or a semiconductor wafer) using a chemical vapor deposition (CVD) method, or oxidizes or diffuses a semiconductor substrate. Particularly, in the first embodiment, the description will be made based on a batch-type substrate processing apparatus that processes a plurality of substrates at a time.

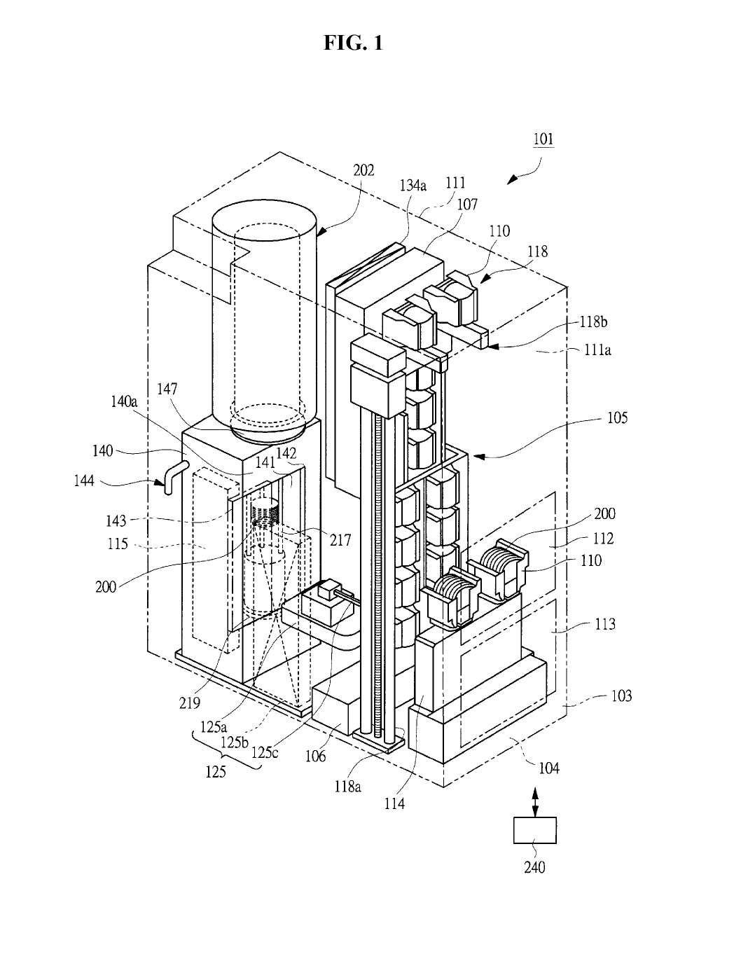

First, the substrate processing apparatus according to the first embodiment will be described with reference to the drawings. FIG. 1 is a diagram illustrating a schematic configuration of the substrate processing apparatus according to the first embodiment. As illustrated in FIG. 1, the substrate processing apparatus 101 according to the first embodiment is configured to use a cassette 110 as a wafer carrier in which a plurality of wafers (or semiconductor substrates) 200, each of which is made of silicon, are contained, and includes a casing 111. A front maintenance port 103 is provided as an opening in a lower part of a front wall 111a of the casing 111 so as to enable maintenance, and a front maintenance door 104 is installed on the front wall 111a of the casing 111 so as to open and close the front maintenance port 103.

The front maintenance door 104 is provided with a cassette loading/unloading port (or a substrate container loading/unloading port) 112 so as to communicate inside and outside of the casing 111 with each other, and the cassette loading/unloading port 112 is opened/closed by a front shutter (or a substrate container loading/unloading port opening/closing mechanism) 113. A cassette stage (or a substrate container transfer table) 114 is installed inside the casing 111 of the cassette loading/unloading port 112. The cassette 110 is loaded onto a cassette stage 114 by an in-process transfer device (not shown), and is unloaded from the cassette stage 114. The cassette stage 114 is configured so that the wafers 200 in the cassette 110 are placed in a vertical posture by the in-process transfer device, with a wafer charging/discharging port of the cassette 110 directed upward.

The casing 111 has a cassette shelf (or a substrate container placement shelf) 105 installed at approximately a lower center thereof in a longitudinal direction. The cassette shelf 105 stores a plurality of cassettes 110 in multiple stages and in multiple rows, and is disposed to allow the wafers 200 in the cassette 110 to be charged/discharged. The cassette shelf 105 is installed on a slide stage (or a horizontal moving mechanism) 106 so as to be movable in a transverse direction. Further, a buffer shelf (or a substrate container storage shelf) 107 is installed on an upper part of the cassette shelf 105. The cassette 110 is also stored in the buffer shelf 107.

A cassette transport device (or a substrate container transfer device) 118 is installed between the cassette stage 114 and the cassette shelf 105. The cassette transfer device 118 is made up of a cassette elevator (or a substrate container elevating mechanism) 118a that is capable of elevating the cassette 110 while holding the cassette 110, and a cassette transferring mechanism (or a substrate container transferring mechanism) 118b as a transferring mechanism. The cassette elevator 118a and the cassette transferring mechanism 118b are continuously operated to allow the cassette 110 to be transferred among the cassette stage 114, the cassette shelf 105, and the buffer shelf 107.

A wafer conveying mechanism (or a substrate conveying mechanism) 125 is installed behind the cassette shelf 105. The wafer conveying mechanism 125 includes a wafer conveying unit (or a substrate conveying unit) 125a that is capable of horizontally rotating or linearly moving the wafer 200, and a wafer conveying unit elevator (or a substrate conveying unit elevating mechanism) 125b configured to elevate the wafer conveying unit 125a. As schematically illustrated in FIG. 1, the wafer conveying unit elevator 125b is installed on a left-hand end portion of the casing 111. The wafer conveying unit elevator 125b and the wafer conveying unit 125a are continuously operated to cause tweezers (or a substrate holder) 125c of the wafer conveying unit 125a to charge or discharge the wafer 200 into or from a susceptor that functions as a placement part of the wafer 200 and is located at a susceptor holding mechanism (not shown).

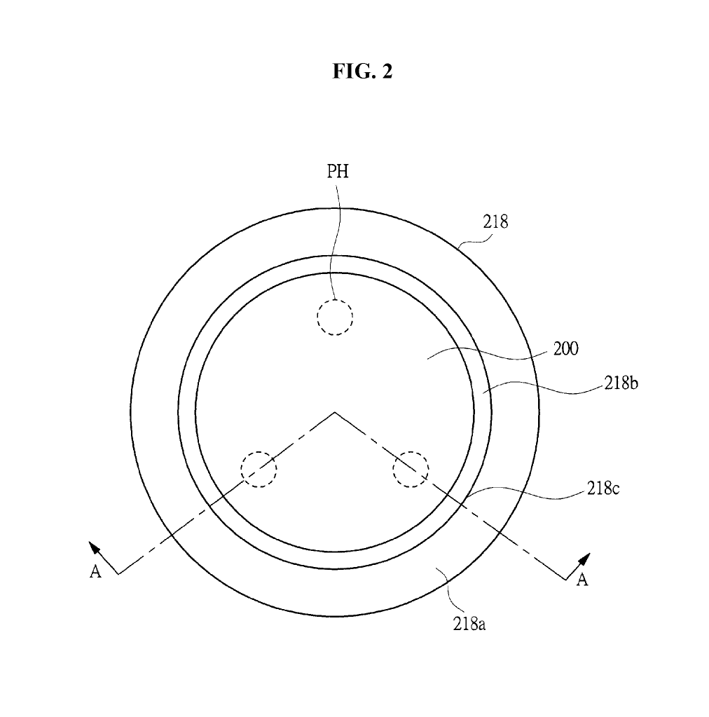

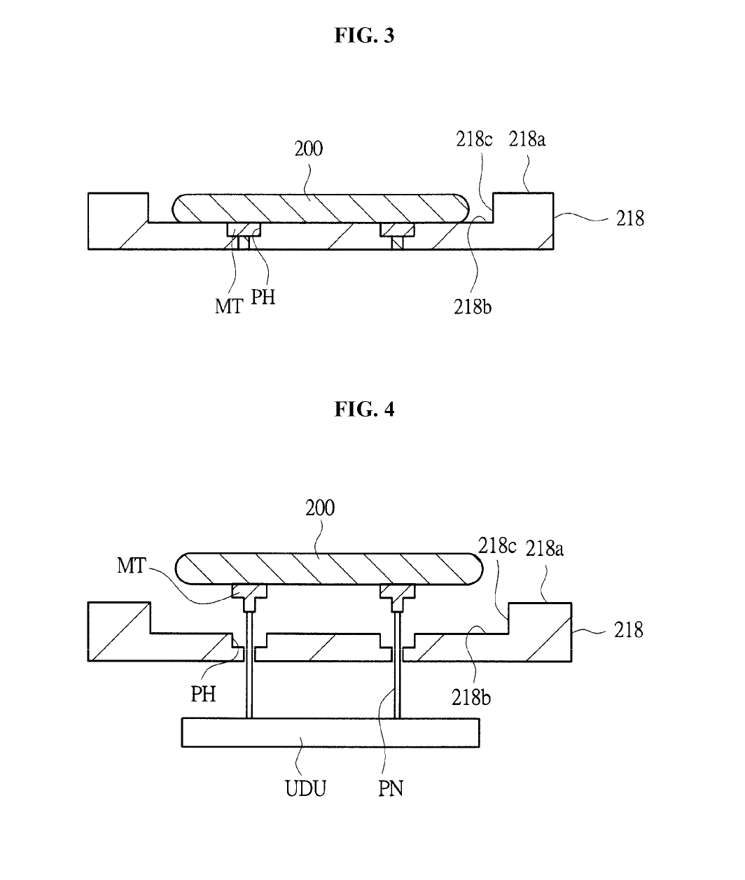

Hereinafter, a state where the wafer 200 is charged into and discharged from the susceptor in the susceptor holding mechanism will be described. FIG. 2 is a plan view illustrating a state where the wafer 200 is charged into the susceptor 208, and FIG. 3 is a cross-sectional view taken along line A-A of FIG. 2. First, as illustrated in FIG. 2, the susceptor 208 has a disc shape, and includes a concentric circumferential part 218a and a circular central part 218b. The disc-shaped wafer 200 is held on the central part 218b of the susceptor 218. That is, the susceptor 218 has the shape of a disc larger than the wafer 200, and the wafer 200 is placed in the central part 218b of the susceptor 218. Further, as illustrated in FIG. 3, the circumferential part 218a of the susceptor 218 is higher than the central part 218b of the susceptor 218, so that the susceptor 218 has a step part 218c formed at a boundary region between the circumferential part 218a and the central part 218b. That is, the susceptor 218 is configured so that the central part 218b is recessed from the circumferential part 218a, and the wafer 200 is held in the recessed central part 218b. In other words, the central part 218b of the susceptor 218 may be formed so as to be thinner than the circumferential part 218a of the susceptor 218. In addition, as illustrated in FIGS. 2 and 3, a plurality of pin holes PH are formed in the central part 218b of the susceptor 218, and a member MT is buried in each pin hole PH. It can be found that the wafer 200 is charged into the susceptor 218, as described above.

Next, an example where the wafer 200 is discharged from the susceptor 218 in the susceptor holding mechanism will be described. FIG. 4 is a cross-sectional view illustrating a process of separating the wafer 200 from the susceptor 218. As illustrated in FIG. 4, the susceptor holding mechanism is provided with elevation pins PN configured to elevate the wafer 200 and an elevation pin elevating mechanism UDU that elevates the elevation pins PN. First, the elevation pins PN are positioned by the susceptor holding mechanism so as to come into contact with the members MT buried in the pin holes PH formed in the susceptor 218, and then the elevation pins PN are elevated by the elevation pin elevating mechanism UDU. Thereby, the wafer 200 is separated from the susceptor 218 along with the members MT buried in the pin holes PH, as shown in FIG. 4. It can be found from this configuration that the wafer 200 is discharged from the susceptor 218. It can be found from this configuration that the wafer 200 can be charged or discharged between the tweezers (or the substrate holder) 125c of the wafer conveying unit 125a and the susceptor 218. In addition, to prevent heat from being emitted from the pin holes PH without damaging the wafer 200 when the wafer 200 is elevated, a leading end of each elevation pin PN is preferably formed in a flange shape.

In the first embodiment, the substrate processing apparatus 101 includes a susceptor moving mechanism (not shown) in addition to the susceptor holding mechanism. The susceptor moving mechanism is configured to charge and discharge the susceptor 218 between the susceptor holding mechanism and a boat (or a substrate holding tool) 217.

Next, as illustrated in FIG. 1, a cleaning unit 134a is installed behind the buffer shelf 107, and is made up of a supply fan and a dust-proof filter so as to supply clean air, a cleaned atmosphere, into the substrate processing apparatus 101. The clean unit 134a is configured to cause the clean air to circulate in the casing 111. In addition, another clean unit (not shown) is installed on a right-hand end portion that is opposite to a side of the wafer conveying unit elevator 125b, and is made up of a supply fan and a dust-proof filter so as to supply clean air. The clean air blown out from the clean unit circulates through the wafer conveying unit 125a, and then is suctioned into an exhaust device (not shown), and is exhausted to the outside of the casing 111.

A pressure-resistant casing 140 is installed behind the wafer conveying unit (substrate conveying unit) 125a, and has airtight performance capable of maintaining a pressure below atmospheric pressure (hereinafter, referred to as “negative pressure”). A load lock chamber (or a transfer chamber) 141, which is a stand-by chamber of a load lock system having a capacity capable of containing a boat 217, is formed by the pressure-resistant casing 140.

A wafer loading/unloading port (or a substrate loading/unloading port) 142 is provided in a front wall 140a of the pressure-resistant casing 140. The wafer loading/unloading port 142 is opened and closed by a gate valve (or a substrate loading/unloading port opening/closing mechanism) 143. A gas supply pipe 144 for feeding an inert gas such as nitrogen gas to the load lock chamber 141 and a gas exhaust pipe (not shown) for exhausting the load lock chamber 141 to a negative pressure are connected to a pair of side walls of the pressure-resistant casing 140, respectively.

A processing furnace (or a reaction furnace) 202 is provided at an upper part of the load lock chamber 141. A lower end portion of the processing furnace 202 is configured to be opened and closed by a furnace port shutter (or a furnace port gate valve or a furnace port opening/closing mechanism) 147.

As schematically illustrated in FIG. 1, a boat elevator (or a support holder elevating mechanism) 115 for elevating the boat 217 is installed in the load lock chamber 141. A seal cap 219, or a lid member, is horizontally installed on an arm (not shown) as a connecting tool connected to the boat elevator 115. The seal cap 219 is configured to vertically support the boat 217 and to allow a lower end portion of the processing furnace 202 to be closed.

The boat 217 includes a plurality of struts (or holding members), and is configured to horizontally hold a plurality of susceptors 218 (e.g. approximately 50 to approximately 150 susceptors) in a state where the plurality of susceptors 218 are concentrically aligned in a vertical direction. Each unit constituting the substrate processing apparatus 101 is electrically connected with a controller 240. The controller 240 is configured to control the operation of each unit constituting the substrate processing apparatus 101.

In the first embodiment, the substrate processing apparatus 101 is generally configured as described above, and the operation thereof will be described below. In the following description, the operation of each unit constituting the substrate processing apparatus 101 is controlled by the controller 240.

As illustrated in FIG. 1, before the cassette 110 is supplied to the cassette stage 114, the cassette loading/unloading port 112 is opened by the front shutter 113. Thereafter, the cassette 110 is loaded through the cassette loading/unloading port 112, and is placed on the cassette stage 114. Here, the wafers 200 placed on the cassette stage 114 are placed in a vertical posture and the wafer charging/discharging port of the cassette 110 is directed upward.

Next, the cassette 110 is elevated from the cassette stage 114 by the cassette transfer device 118, and is rotated in the rear of the casing 111 in a rightward, longitudinal direction by an angle of 90°, so that the wafers 200 in the cassette 110 are placed in a horizontal posture, and the wafer charging/discharging port of the cassette 110 is directed to the rear of the casing 111. Subsequently, the cassette 110 is automatically transferred to a designated position of the cassette shelf 105 or the buffer shelf 107 by the cassette transfer device 118. The cassette 110 is stored temporarily, and then is conveyed to the cassette shelf 105 or directly transferred to the cassette shelf 105 by the cassette transfer device 118.

Thereafter, the slide stage 106 moves the cassette shelf 105 horizontally, and positions the cassette 110 to be conveyed so as to face the wafer conveying unit 125a. The wafer 200 is picked up from the cassette 110 through the wafer charging/discharging port by the tweezers 125c of the wafer conveying unit 125a. Here, in the susceptor holding mechanism, the elevation pins are elevated by the elevation pin elevating mechanism. Subsequently, the wafer 200 is placed on the elevation pins by the wafer conveying unit 125a. The wafer 200 is held on the susceptor by the elevation pin elevating mechanism by lowering the elevation pins on which the wafer 200 is placed.

Next, when the wafer loading/unloading port 142 of the load lock chamber 141, an inside of which is previously set in an atmospheric state, is opened by the operation of the gate valve 143, the susceptor is discharged from the susceptor holding mechanism by the susceptor moving mechanism. The susceptor discharged by the susceptor moving mechanism is loaded into the load lock chamber 141 through the wafer loading/unloading port 142, and is charged into the boat 217.

The wafer conveying unit 125a returns to the cassette 110, and charges the next wafer 200 into the susceptor holding mechanism. The susceptor moving mechanism returns to the susceptor holding mechanism, and charges the susceptor on which the wafer 200 is placed into the boat 217.

When previously designated susceptors are charged into the boat 217, the wafer loading/unloading port 142 is closed by the gate valve 143. Then, the lower end portion of the processing furnace 202 is opened by the furnace port shutter (or the furnace port gate valve) 147. Subsequently, the seal cap 219 is elevated by the boat elevator 115, and the boat 217 supported by the seal cap 219 is loaded into the processing furnace 202.

After the boat 217 is loaded, arbitrary processing is performed on the wafer 200 in the processing furnace 202. After the wafer 200 is processed, the boat 217 is taken out by the boat elevator 115, and the gate valve 143 is also opened. Thereafter, the processed wafer 200 and the cassette 110 are discharged to the outside of the casing 111 by an operation substantially opposite to the aforementioned operation. As described above, the substrate processing apparatus 101 according to the first embodiment is operated.

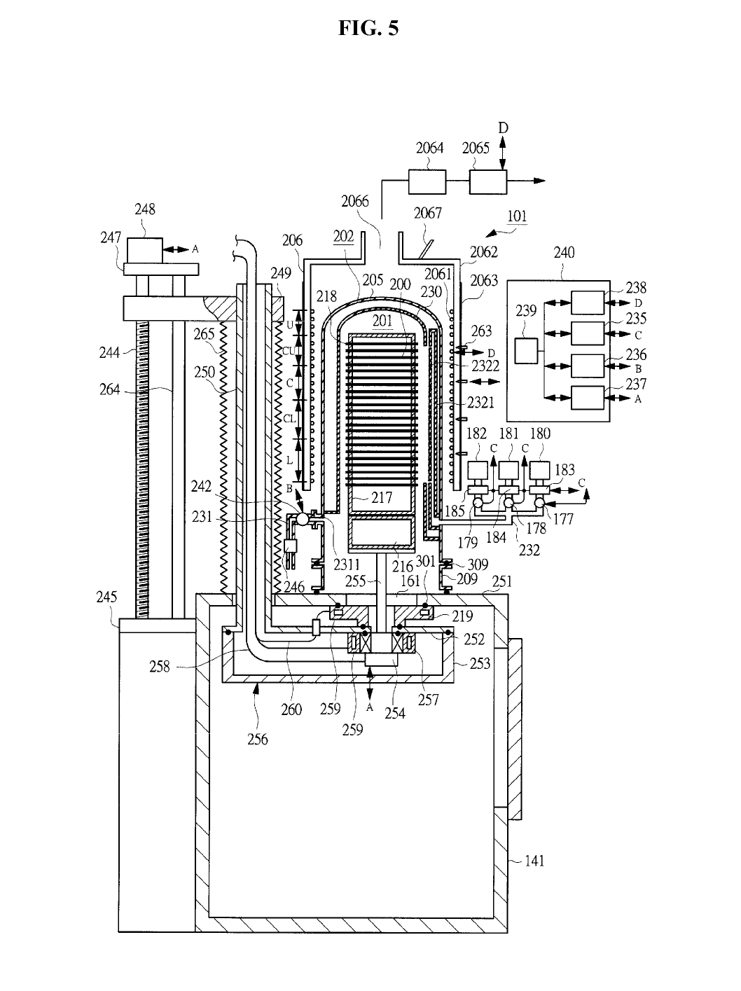

Next, the processing furnace 202 of the substrate processing apparatus 101 according to the first embodiment will be described with reference to the drawings. FIG. 5 is a schematic configuration of the processing furnace 202 of the substrate processing apparatus 101 and a configuration of the surroundings of the processing furnace 202 in the first embodiment, and is shown as a longitudinal cross-sectional view.

As illustrated in FIG. 5, the processing furnace 202 includes an induction heating unit 206 that is heated by applying high-frequency current. The induction heating unit 206 is formed in a cylindrical shape, and is made up of a radio frequency (RF) coil 2061 as an induction heating unit, a wall member 2062, and a cooling wall 2063. The RF coil 2061 is connected to a high-frequency power supply (not shown), and the high-frequency current flows to the RF coil 2061 by means of the high-frequency power supply.

The wall member 2062 is formed of metal such as a stainless material. The wall member 2062 has a cylindrical shape, and the RF coil 2061 is installed on an inner wall of the wall member 2062. The RF coil 2061 is supported by a coil support (not shown). The coil support is supported by the wall member 2062 with a predetermined gap formed in a radial direction between the RF coil 2061 and the wall member 2062.

The cooling wall 2063 is installed on an outer wall of the wall member 2062 so as to be concentric with the wall member 2062. The wall member 2062 is provided with an opening 2066 in the center of an upper end thereof. A duct is connected on a downstream side of the opening 2066. A radiator 2064 as a cooling unit and a blower 2065 as an exhaust unit are connected on a downstream side of the duct.

The cooling wall 2063 is provided with a cooling medium channel in almost an entire region thereof so as to allow a cooling medium, for instance cooling water, to circulate therein. A cooling medium supply unit configured to supply a cooling medium (not shown) and a cooling medium exhaust unit configured to exhaust the cooling medium are connected to the cooling wall 2063. The cooling wall 2063 is cooled by supplying the cooling medium from the cooling medium supply unit to the cooling medium channel and by exhausting the cooling medium through the cooling medium exhaust unit, and the wall member 2062 and an inside of the wall member 2062 are cooled by thermal conduction.

An outer tube 205 is installed inside the RF coil 2061, and functions as a reaction tube constituting a reaction vessel in a shape concentric with the induction heating unit 206. The outer tube 205 is formed of quartz (SiO₂) as a heat-resistant material, and has a cylindrical shape where its upper end is closed and its lower end is opened. An inner tube 230 is installed inside the outer tube 205. A processing chamber 201 is formed inside the inner tube 230. The wafers 200 are contained in the processing chamber 201 as the semiconductor substrates in a horizontal posture in a state where the wafers 200 are vertically aligned in multiple stages by the boat 217 and the susceptor 218 as an induced member.

A manifold 209 is disposed below the outer tube 205 in a shape concentric with the outer tube 205. The manifold 209 is formed of, for instance, quartz (SiO₂) or stainless, and is formed in a cylindrical shape where its upper and lower ends are open. This manifold 209 is provided to support the outer tube 205. In addition, an O-ring 309 is provided as a seal member between the manifold 209 and the outer tube 205. The manifold 209 is supported by a holding member (not shown), so that the outer tube 205 is installed vertically. Thus, the reaction vessel is defined by the outer tube 205 and the manifold 209. Here, the manifold 209 is not particularly limited to a case where the manifold 209 is installed independently of the outer tube 205. The manifold 209 may be installed not individually, but integrally with the outer tube 205.

A gas supply nozzle 2321 formed of quartz (SiO₂) to laterally supply gas to each wafer 200 disposed in the processing chamber 201, and a gas exhaust port 2311 formed of quartz (SiO₂) to laterally exhaust the gas passing through each wafer 200 disposed in the processing chamber 201 are formed inside a sidewall of the outer tube 205.

The gas supply nozzle 2321 is installed inside the sidewall of the outer tube 205, has a closed upper end, and the sidewall is provided with a plurality of gas supply ports 2322 in a sidewall thereof. Here, the gas supply nozzle 2321 is preferably installed at a plurality of places so as to allow a gas to be uniformly supplied to each of the plurality of wafers 200 placed on the boat 217. Further, the gas supply nozzle 2321 is preferably installed so that gas supply directions from the plurality of gas supply ports 2322 are parallel to each other. In addition, a plurality of gas supply nozzles 2321 may be installed at positions having line symmetry with respect to the center of the wafer 200. Each gas supply port 2322 may be installed at a position of a predetermined height from the upper surface of the wafer 200 in the gap between the wafers 200 so as to allow a gas to be uniformly supplied to each of the plurality of wafers 200 placed on the boat 217.

A gas exhaust pipe 231 communicating with the gas exhaust port 2311 and a gas supply pipe 232 communicating with the gas supply nozzle 2321 are installed on a lower outer sidewall of the outer tube 205. Further, the gas exhaust pipe 231 may not be installed on the lower outer sidewall of the outer tube 205. For example, the gas exhaust pipe 231 may be installed on the sidewall of the manifold 209. A communication part of the gas supply pipe 232 with the gas supply nozzle 2321 may not be installed on the lower outer sidewall of the outer tube 205. For example, the communication part may be installed on the sidewall of the manifold 209.

The gas supply pipe 232 is divided into three tubes on an upstream side thereof which are connected to a first gas supply source 180, a second gas supply source 181, and a third gas supply source 183 via valves 177, 178 and 179 and mass flow controllers (MFCs) 183, 184 and 185 as gas flow rate control units, respectively. A gas flow rate control unit 235 is electrically connected to the MFCs 183, 184 and 185 and the valves 177, 178 and 179. A flow rate of a supplied gas is controlled at a desired timing so as to maintain a desired flow rate by the gas flow rate control unit 235.

A vacuum exhaust unit 246 such as a vacuum pump is connected to a downstream side of the gas exhaust pipe 231 via a pressure sensor (not shown) serving as a pressure detector and an automatic pressure control (APC) valve 242 serving as a pressure regulator. A pressure control unit 236 is electrically connected to the pressure sensor and the APC valve 242. The pressure control unit 236 is configured to adjust the degree of opening of the APC valve 242 based on a pressure detected by the pressure sensor, thereby controlling pressure in the processing chamber 201 at a desired timing so as to maintain a desired pressure.

The seal cap 219 is provided below the manifold 209, and functions as a furnace port lid member configured to airtightly close a lower end opening of the manifold 209. The seal cap 219 is formed of metal such as stainless, and is formed in a disc shape. An O-ring 301 is provided on an upper surface of the seal cap 219, and functions as a seal member that abuts the lower end of the manifold 209.

A rotating mechanism 254 is installed in the seal cap 219. A rotary shaft 255 of the rotating mechanism 254 is configured to pass through the seal cap 219, to be connected to the boat 217, and to rotate the wafer 200 by rotating the boat 217.

The seal cap 219 is configured to be elevated in a vertical direction by an elevating motor 248 as an elevating mechanism that is installed outside the processing furnace 202. Thereby, the boat 217 can be loaded and unloaded with respect to the processing chamber 201.

A drive control unit 237 is electrically connected to the rotating mechanism 254 and the elevating motor 248. The drive control unit 237 is configured to control the rotating mechanism 254 and the elevating motor 248 so as to perform a desired operation at a desired timing.

Next, the spiral-shaped RF coil 2061 is installed on the induction heating unit 206 in such a manner that it is divided into a plurality of regions (or zones) in a vertical direction. For example, as illustrated in FIG. 5, the RF coil 2061 is divided into five zones from the lower zone: an RF coil L, an RF coil CL, an RF coil C, an RF coil CU, and an RF coil U. The RF coils divided into the five zones are independently controlled.

A radiation thermometer 263 is installed, for instance, at four places around the induction heating unit 206, and functions as a temperature detecting member that detects temperature in the processing chamber 201. At least one radiation thermometer 263 may be provided. However, a plurality of radiation thermometers 263 are provided so as to improve temperature controllability.

A temperature control unit 238 is electrically connected to the induction heating unit 206 and the radiation thermometer 263. The electrical conduction to the induction heating unit 206 can be adjusted based on information on the temperature detected by the radiation thermometer 263. The temperature control unit 238 controls the temperature in the processing chamber 201 at a desired timing, so as to have a desired temperature distribution.

The temperature control unit 238 is electrically connected to the blower 2065 as well. The temperature control unit 238 is configured to control the operation of the blower 2065 according to a preset operation recipe. The blower 2065 is operated to discharge atmosphere in the gap between the wall member 2062 and the outer tube 205 through the opening 2066. After being discharged through the opening 2066, the atmosphere is cooled by a radiator 2064, and then is discharged from a downstream side of the blower 2065 to equipment. That is, the blower 2065 is operated under the control of the temperature control unit 238, so that the induction heating unit 206 and the outer tube 205 can be cooled.

The cooling medium supply unit and the cooling medium exhaust unit, both of which are connected to the cooling wall 2063, are configured to be controlled at a predetermined timing by a controller 240 so that a flow rate of the cooling medium on the cooling wall 2063 is cooled in a desired state. It is further preferable to provide the cooling wall 2063, because it is easy to prevent heat from being radiated to an outside of the processing furnace 202, and because the outer tube 205 is more easily cooled. However, when the cooled state caused by the cooling of the blower 2065 can be controlled in a desired cooled state, the cooling wall 2063 may not be provided.

Further, an explosion release port and an explosion release port opening/closing unit 2067 configured to open and close the explosion release port are installed at an upper end of the wall member 2062, in addition to the opening 2066. When hydrogen and oxygen gases are mixed and exploded in the wall member 2062, a predetermined high pressure is applied to the wall member 2062. For this reason, places having relatively weak strength, for instance bolts, screws, and panels forming the wall member 2062, are destroyed or scattered, so that damage increases. To minimize this damage, the explosion release port opening/closing unit 2067 is configured to open the explosion release port at a predetermined pressure or higher when explosion occurs in the wall member 2062, thereby releasing internal pressure.

Next, the configuration of the surroundings of the processing furnace 202 in the first embodiment will be described with reference to FIG. 5. A lower base plate 245 is installed on an outer surface of the load lock chamber 141 as a preliminary chamber. The lower base plate 245 is provided with a guide shaft 264 engaged with an elevation table 249 and a ball screw 244 screwed with the elevation table 249. An upper base plate 247 is installed at upper ends of the guide shaft 264 and the ball screw 244, both of which are erected on the lower base plate 245. The ball screw 244 is rotated by the elevating motor 248 installed on the upper base plate 247. The elevation table 249 is configured to be elevated by the rotation of the ball screw 244.

A hollow elevation shaft 250 is installed on the elevation table 249 in a vertical direction, and a joint for the elevation table 249 and the elevation shaft 250 is in an airtight state. The elevation shaft 250 is elevated together with the elevation table 249. The elevation shaft 250 passes through a top plate 251 of the load lock chamber 141. A through hole of the top plate 251, through which the elevation shaft 250 passes, has sufficient room so as not to be brought into contact with the elevation shaft 250. A bellows 265, as a hollow flexible member having flexibility so as to cover surroundings of the elevation shaft 250, is provided between the load lock chamber 141 and the elevation table 249 in order to keep the load lock chamber 141 airtight. The bellows 265 has a sufficient expansion amount capable of corresponding to an elevation amount of the elevation table 249. The bellows 265 is configured so that an inner diameter of the bellows 265 is sufficiently larger than an outer shape of the elevation shaft 250 and the bellows 265 is not brought into contact with the elevation shaft 250 by its expansion.

An elevation base plate 252 is horizontally fixed to a lower end of the elevation shaft 250. A drive unit cover 253 is air-tightly installed on a lower surface of the elevation base plate 252 via a seal member such as an O-ring. A drive unit receiving case 256 is constituted of the elevation base plate 252 and the drive unit cover 253. With this configuration, an inside of the drive unit receiving case 256 is separated from an atmosphere of the load lock chamber 141.

Further, the rotating mechanism 254 of the boat 217 is installed in the drive unit receiving case 256, and a circumferential part of the rotating mechanism 254 is cooled by a cooling mechanism 257.

In addition, a power supply cable 258 is guided from an upper end of the elevation shaft 250 to the rotating mechanism 254 through a hollow part of the elevation shaft 250, and is connected to the rotating mechanism 254. Cooling channels 259 are formed in the cooling mechanism 257 and the seal cap 219. A cooling water piping 260 configured to supply cooling water is connected to the cooling channels 259, and extends from the upper end of the elevation shaft 250 through the hollow part of the elevation shaft 250.

By driving the elevating motor 248 to rotate the ball screw 244, the drive unit receiving case 256 is elevated via the elevation table 249 and the elevation shaft 250.

When the drive unit receiving case 256 is elevated, the furnace port 161, i.e. the opening of the processing furnace 202, is closed by the seal cap 219 that is air-tightly installed on the elevation base plate 252, so that the wafer can be processed. When the drive unit receiving case 256 is lowered, the boat 217 is lowered together with the seal cap 219, so that the wafer 200 can be unloaded to the outside.

The gas flow rate control unit 235, the pressure control unit 236, the drive control unit 237, and the temperature control unit 238 constitute an operation unit and an input/output unit, and are electrically connected to a main control unit 239 configured to control the entire substrate processing apparatus 101. The gas flow rate control unit 235, the pressure control unit 236, the drive control unit 237, the temperature control unit 238, and the main control unit 239 constitutes a controller 240. As described above, the structure of the processing furnace 202 of the substrate processing apparatus 101 and the structure of the surroundings of the processing furnace 202 in the first embodiment are obtained.

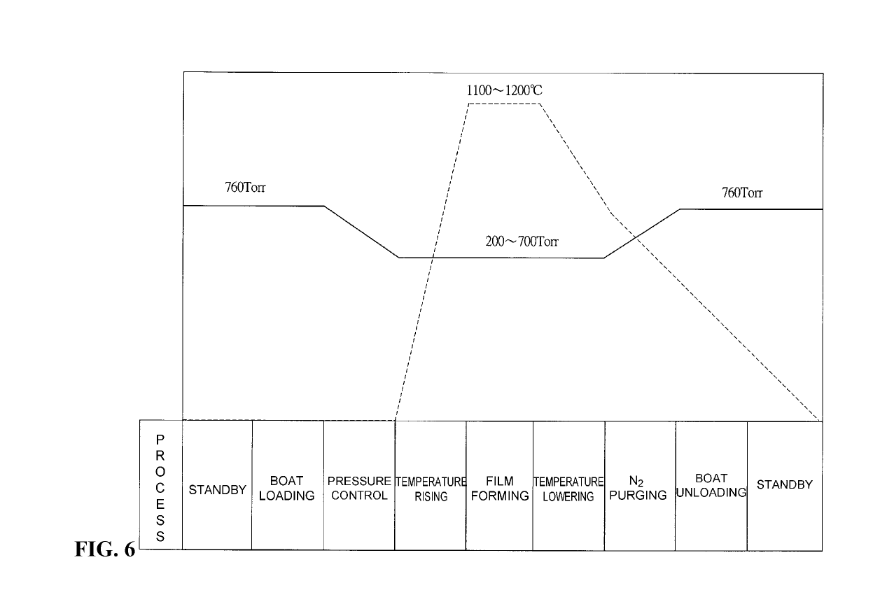

Next, processes of processing a substrate using the substrate processing apparatus according to the first embodiment will be described with reference to FIGS. 5 and 6. In detail, in the first embodiment, as one of the substrate processing processes, a method of forming a semiconductor film such as a silicon film on a substrate such as a wafer 200 (or a method of manufacturing a semiconductor device) using an epitaxial growth method will be described. FIG. 6 illustrates a sequence of the processes of manufacturing a semiconductor device. A broken line of FIG. 6 indicates a temperature in the processing chamber 201, and a solid line of FIG. 6 indicates a pressure in the processing chamber 201. In the following description, the operation of each unit constituting the substrate processing apparatus 101 according to the first embodiment is controlled by the controller 240.

First, before the boat 217 is loaded into the processing chamber 201, the processing chamber 201 is in a standby state (standby of FIG. 6). The standby state refers to a state where the boat 217 is disposed in the load lock chamber 141 just below the processing chamber 201 and a plurality of susceptors 218, on each of which the wafer 200 is placed, is charged into the boat 217.

When the plurality of susceptors 218 on which the wafers 200 are placed are charged into the boat 217, the boat 217 configured to hold the plurality of susceptors 218 is loaded (boat-loaded) into the processing chamber 201 by an elevating operation of the elevation table 249 and the elevation shaft 250 driven by the elevating motor 248, as shown in FIG. 5 (boat loading of FIG. 6). In this state, the seal cap 219 is in a state of sealing the lower end of the manifold 209 via the O-ring. Here, the pressure in the processing chamber 201 reaches, for instance, 760 Torr (=760×133.3 Pa).

Subsequently, an inside of the processing chamber 201 is exhausted by the vacuum exhaust unit 246 so as to be a desired pressure. Here, the pressure in the processing chamber 201 is measured by the pressure sensor, and the APC valve (or the pressure regulator) 242 is feedback-controlled based on the measured pressure (pressure control of FIG. 6). The pressure in the processing chamber 201 ranges, for instance, from 200 Torr to 760 Torr (from 200×133.3 Pa to 760×133.3 Pa) by means of the pressure control process.

The blower 2065 is operated, a gas or air circulates between the induction heating unit 206 and the outer tube 205, and a sidewall of the outer tube 205, the gas supply nozzle 2321, the gas supply port 2322, and the gas exhaust port 2311 are cooled. Cooling water circulates through the radiator 2064 and the cooling wall 2063 as a cooling medium, and an inside of the induction heating unit 206 is cooled via the wall member 2062. Further, high-frequency current is applied to the induction heating unit 206 so that the wafers 200 are heated to a desired temperature, thereby generating induced current (overcurrent) in the susceptors 218.

In detail, the induction heating unit 206 performs induction heating on the plurality of susceptors 218 that are at least held in the boat 217 in the processing furnace 202, thereby heating the wafer 200 placed on each susceptor 218 (temperature rising of FIG. 6). That is, when the high-frequency current is caused to flow to the induction heating unit 206, a high-frequency electromagnetic field is generated in the processing furnace 202, and overcurrent is generated in each susceptor 218 as an induced member by the high-frequency electromagnetic field. Each susceptor 218 is subjected to induction heating by the overcurrent, so that each susceptor 218 is heated. Particularly, since the overcurrent is generated in the circumferential part of each susceptor 218 as the induced member, the circumferential part of each susceptor 218 is mainly heated by the induction heating of the induction heating unit 206. In each susceptor 218 whose circumferential part is heated, heat flows from the circumferential part of each susceptor 218 to the central part of each susceptor 218 by thermal conduction, so that all parts (the circumferential part and the central part) of each susceptor 218 are heated. When each susceptor 218 is heated in this way, the heat is transferred to the wafer 200 held on the susceptor 218 by the thermal conduction, so that the wafer 200 is heated.

In this substrate processing apparatus 101 according to the first embodiment, a method of heating the wafer 200 using an induction heating method is employed. Here, even when the wafer 200 is directly subjected to the induction heating by the high-frequency electromagnetic field generated by causing the high-frequency current to flow to the induction heating unit 206, a heating amount is frequently insufficient. Thus, this induction heating method uses the susceptor 218 as the induced member so as to allow the susceptor to be efficiently heated by the induction heating. That is, in the substrate processing apparatus 101 using the induction heating method, the susceptor 218 is used so as to be efficiently heated by the induction heating. The susceptor 218 is efficiently heated by the induction heating, and then the wafer 200 placed on the heat susceptor 218 is heated by the thermal conduction from the susceptor 218. It can be seen from this configuration that the susceptor 218 has a function of holding the wafer 200 as well as a characteristic of undergoing the induction heating by means of the high-frequency electromagnetic field as an important function.

Here, the electrical conduction to the induction heating unit 206 is feedback-controlled based on temperature information detected by the radiation thermometer 263 so that the inside of the processing chamber 201 has a desired temperature distribution. Further, the blower 2065 is controlled with a preset control amount so that the temperatures of the sidewall of the outer tube 205, the gas supply nozzle 2321, the gas supply port 2322, and the gas exhaust port 2311 are lowered to a temperature, for instance 600° C. or less, that is significantly lower than that at which the film grows on the wafer 200. The wafer 200 is heated to a temperature of, for instance, 1100° C. to 1200° C. Further, the wafer 200 is heated to a fixed temperature among processing temperatures selected within a range of 700° C. to 1200° C. However, even in the case of an arbitrary processing temperature, the blower 2065 is controlled with a preset control amount so that temperatures of the sidewall of the outer tube 205, the gas supply nozzle 2321, the gas supply port 2322, and the gas exhaust port 2311 are lowered to a temperature, for instance 600° C. or less, that is significantly lower than that at which the film grows on the wafer 200.

Subsequently, the boat 217 is rotated by the rotating mechanism 254, and thereby the susceptor 218 and the wafer 200 placed on the susceptor 218 are rotated.

Next, SiH₂Cl₂ (dichlorosilane) or SiHCl₃ (trichlorosilane) as a processing gas based on Si or SiGe (silicon germanium), B₂H₆ (diboran), BCl₃ (boron trichloride), or PH₃ (phosphine) as a doping gas, and hydrogen (H₂) as a carrier gas are encapsulated in the first gas supply source 180, the second gas supply source 181, and the third gas supply source 182, respectively. The respective processing gases are supplied from the first gas supply source 180, the second gas supply source 181, and the third gas supply source 182 at a place where the temperature of the wafer 200 is stabilized. After the opening degrees of the MFCs 183, 184, and 185 are adjusted to obtain a desired flow rate, the valves 177, 178, and 179 are opened. Thereby, each processing gas circulates through the gas supply pipe 232 and flows into the gas supply nozzle 2321. Since the gas supply nozzle 2321 has a channel cross-sectional area that is sufficiently larger than an opening area of the plurality of gas supply ports 2322, the gas supply nozzle 2321 has higher pressure than the processing chamber 201, and the gas discharged through each gas supply port 2322 is supplied to the processing chamber 201 at a uniform flow rate and velocity. The gas supplied to the processing chamber 201 passes through the inside of the processing chamber 201, and is discharged to the gas exhaust port 2311. Thereafter, the discharged gas is exhausted to the gas exhaust pipe 231 through the gas exhaust port 2311. The processing gas is heated from the susceptors 218 adjacent to each other in a vertical direction when passing through the gap between the susceptors 218, and is brought into contact with the heated wafer 200, so that a semiconductor film such as a silicon (Si) film is formed on the surface of the wafer 200 by epitaxial growth (film forming of FIG. 6).

When a preset time has elapsed, the temperature of the processing chamber 201 is lowered (temperature lowering of FIG. 6). An inert gas (e.g., N₂ gas) is supplied from an inert gas supply source (not shown), so that the inside of the processing chamber 201 is replaced with the inert gas, and the pressure in the processing chamber 201 returns to a normal pressure (N₂ purging of FIG. 6).

Thereafter, the seal cap 219 is lowered by the elevating motor 248. Thereby, the lower end of the manifold 209 is opened, and the processed wafer 200 is unloaded (boat-unloaded) from the lower end of the manifold 209 toward an outside of the outer tube 205 in a state where it is held on the boat 217 (boat unloading of FIG. 6). Thereafter, the processed wafer 200 is taken out from the boat 217 (wafer discharging), and the processing chamber 201 is transited to the standby state. With the configuration as described above, the semiconductor film can be formed on the wafer 200.

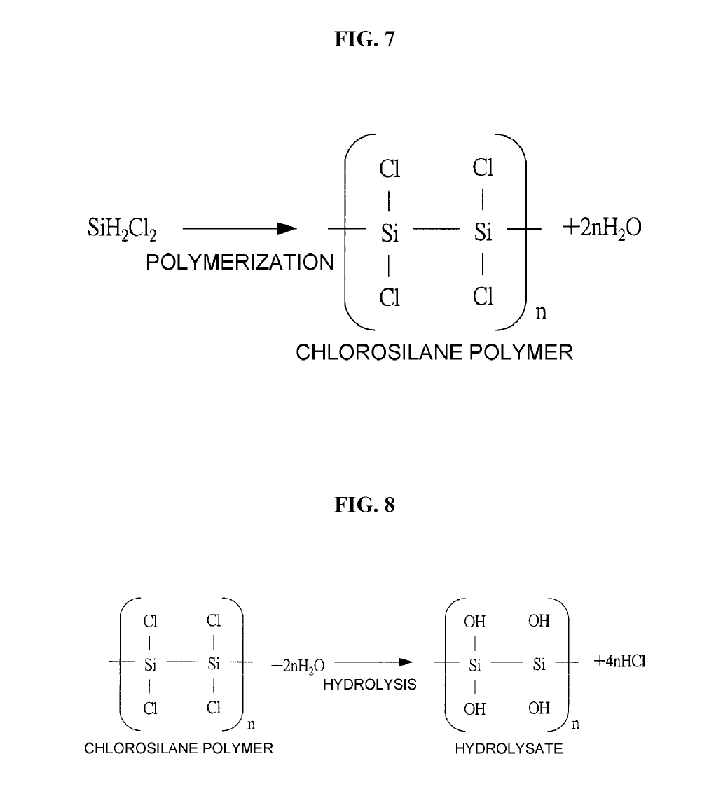

In the process of forming the semiconductor film, a compound having a chlorine (Cl) atom in a chemical formula, such as SiH₂Cl₂ (dichlorosilane) or SiHCl₃ (trichlorosilane), is used as a source gas. In this case, for example, SiH₂Cl₂ (dichlorosilane), the source gas, is pyrolized and polymerized by a chemical reaction as illustrated in FIG. 7, and a by-product such as a chlorosilane polymer is produced as one reaction product. The produced chlorosilane polymer is adhered to and deposited on the inside of the processing chamber 201 and the inner wall of the gas exhaust pipe 231 that is the exhaust line.

Here, in the substrate processing apparatus 101, the processing chamber 201 and the load lock chamber 141 as the convey chamber are provided, and the boat 217, as the holder that holds a plurality of wafers 200, is loaded from the load lock chamber 141 into the processing chamber 201, so that the film forming is performed on the wafers 200. After the film forming is completed, the boat 217 that holds the plurality of wafers 200 is unloaded from the processing chamber 201 to the load lock chamber 141. In the loading or unloading process, since the furnace port 161 provided in the processing chamber 201 is opened to load or unload the boat 217, the air is mixed from the load lock chamber 141 into the processing chamber 201 via the open furnace port 161. Further, since the aforementioned by-product is deposited on the inner wall of the gas exhaust pipe 231 that is the exhaust line connected with the processing chamber 201, it is necessary to perform maintenance on the gas exhaust pipe 231. During the maintenance of the gas exhaust pipe 231, an inside of the gas exhaust pipe 231 is exposed to the air.

Thus, the chlorosilane polymer adhered to the inside of the processing chamber 201 or the inner wall of the gas exhaust pipe 231 is brought into contact with the air when the boat 217 is loaded or unloaded between the load lock chamber 141 and the processing chamber 201 or when the gas exhaust pipe 231 undergoes maintenance. When the chlorosilane polymer is brought into contact with the air in this way, the chlorosilane polymer is gradually hydrolyzed by the moisture (H₂O) in the air, and is changed into a high-combustible hydrolysate by means of the chemical reaction as illustrated in FIG. 8. Further, hydrogen chloride gas is produced by the hydrolysis. For this reason, there is a risk of the high-combustible hydrolysate being abruptly burnt by impact or static electricity during the maintenance. Further, there is a risk of the hydrogen chloride gas produced by the hydrolysis corroding the inside of the processing chamber 201 or the furnace port 161 itself, and leaking from the furnace port 161 to the load lock chamber 141 to corrode the load lock chamber 141.

As such, in the first embodiment, research on preventing the deposition of the high-combustible hydrolysate produced by the aforementioned mechanism and the corrosion caused by the hydrogen chloride gas is being made. In detail, in the first embodiment, attention is paid to the fact that, when the chlorosilane polymer formed as the by-product continues to react with the moisture, the chlorosilane polymer is changed into siloxane, which is a stable material. That is, the first embodiment uses the technical idea that the chlorosilane polymer is changed into the high-combustible hydrolysate when reacting with the moisture in the air first, but it is changed into the siloxane, which is stable, when continuing to react with the moisture. That is, the chlorosilane polymer is deposited on the inside of the processing chamber 201 after the film forming is performed. However, the technical idea in the first embodiment is to change the chlorosilane polymer into the siloxane that is a final product and a stable material rather than the high-combustible hydrolysate that is an intermediate product by causing the deposited chlorosilane polymer to positively react with the air. In other words, the technical idea in the first embodiment is not to remove the chlorosilane polymer itself adhered to the inside of the processing chamber 201 or the inner wall of the gas exhaust pipe 231, but to change the chlorosilane polymer into the siloxane, which is stable, rather than the high-combustible hydrolysate by sufficiently supplying the air to the chlorosilane polymer.

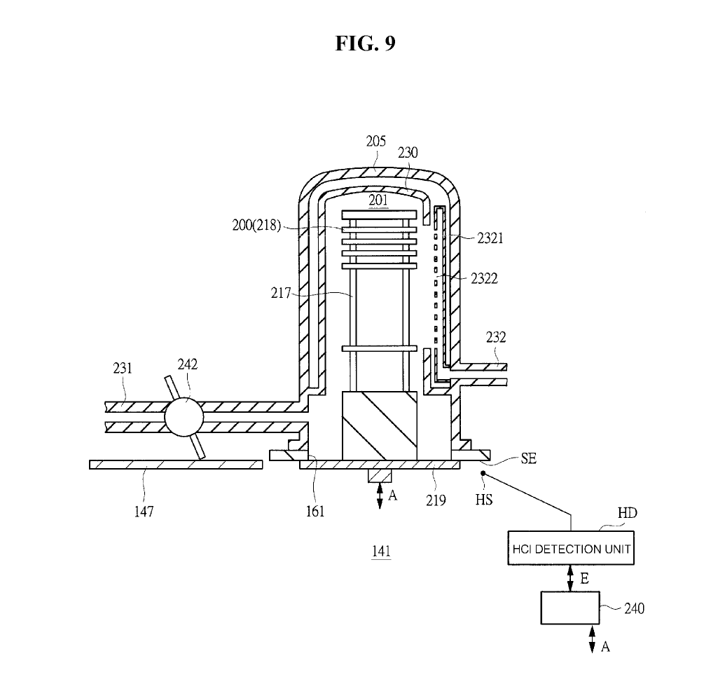

Hereinafter, the features of the substrate processing apparatus according to the first embodiment and a substrate processing method using the same will be described with reference to the drawings. FIG. 9 schematically illustrates configuration of the surroundings of the processing chamber 201 of the substrate processing apparatus according to the first embodiment. The substrate processing apparatus according to the first embodiment has the configuration of FIG. 1 or FIG. 5, but it will be described below using the diagram illustrated in FIG. 9 in order to emphasize the features of the first embodiment.

In FIG. 9, the substrate processing apparatus according to the first embodiment includes the cylindrical outer tube 205. The inner tube 230 is provided inside the outer tube 205. An inside of the inner tube 230 constitutes the processing chamber 201. The gas supply pipe 232 is connected to the outer tube 205. The gas supply pipe 232 is connected with the gas supply nozzle 2321 provided in a gap between the outer tube 205 and the inner tube 230. A plurality of gas supply ports 2322 are formed in the gas supply nozzle 2321. Further, the gas exhaust pipe 231 is connected to a side opposite one side of the outer tube 205 connected with the gas supply pipe 232. The APC valve 242 is installed on the gas exhaust pipe 231.

Subsequently, the boat 217, in which a plurality of susceptors 218 holding the wafers 200 are contained, is disposed in the processing chamber 201. The boat 217 is held on the seal cap 219. By bringing the seal cap 219 into contact with a seal surface SE, the furnace port 161 of the processing chamber 201 is sealed by the seal cap 219. Further, when the boat 217 is disposed in the processing chamber 201, the furnace port shutter 147 is withdrawn so as to be removed from a position just below the furnace port 161.

The load lock chamber 141 is installed below the processing chamber 201 whose furnace port 161 is closed by the seal cap 219. A sensor HS configured to detect hydrogen chloride gas is installed in the load lock chamber 141 at a position adjacent to the furnace port 161. The sensor HS is connected with an HCl detection unit HD. The HCl detection unit HD is configured to detect a concentration level of the hydrogen chloride gas, based on the output of the sensor HS. The HCl detection unit HD is connected with the controller 240, and is controlled by the controller 240. Further, the controller 240 controls the seal cap 219 so as to move up and down. Accordingly, the substrate processing apparatus according to the first embodiment is configured to move the seal cap 219 in a vertical direction under the control of the controller 240, thereby allowing the boat 217 to be loaded from the load lock chamber 141 into the processing chamber 201 or to be unloaded from the processing chamber 210 to the load lock chamber 141.

The substrate processing apparatus according to the first embodiment is configured as described above, and the features of the method of processing the substrate using the same will be described below. In the first embodiment, the characteristic process is performed in a process of unloading the boat 217 from the processing chamber 201 after film forming is completed (boat unloading process).

FIG. 9 illustrates a state after a film-forming process. In the film-forming process of FIG. 9, as described above, SiH₂Cl₂ (dichlorosilane), a source gas, is subjected to pyrolysis and polymerization, and a by-product such as a chlorosilane polymer is produced. The produced chlorosilane polymer is adhered to and deposited on the inside of the processing chamber 201 and the inner wall of the gas exhaust pipe 231 that is the exhaust line. In this state, when the boat 217 is lowered into the load lock chamber 141 by the control of the controller 240, the furnace port 161 of the processing chamber 201 is opened, so that the air is mixed into the processing chamber 201 through the opened furnace port 161. Then, the chlorosilane polymer, which is adhered to the inside of the processing chamber 201 and the inner wall of the gas exhaust pipe 231, reacts with the air, so that a high-combustible hydrolysate is produced and hydrogen chloride gas is generated. The generated hydrogen chloride gas corrodes the furnace port 161 itself, and flows into the load lock chamber 141 to corrode the load lock chamber 141.

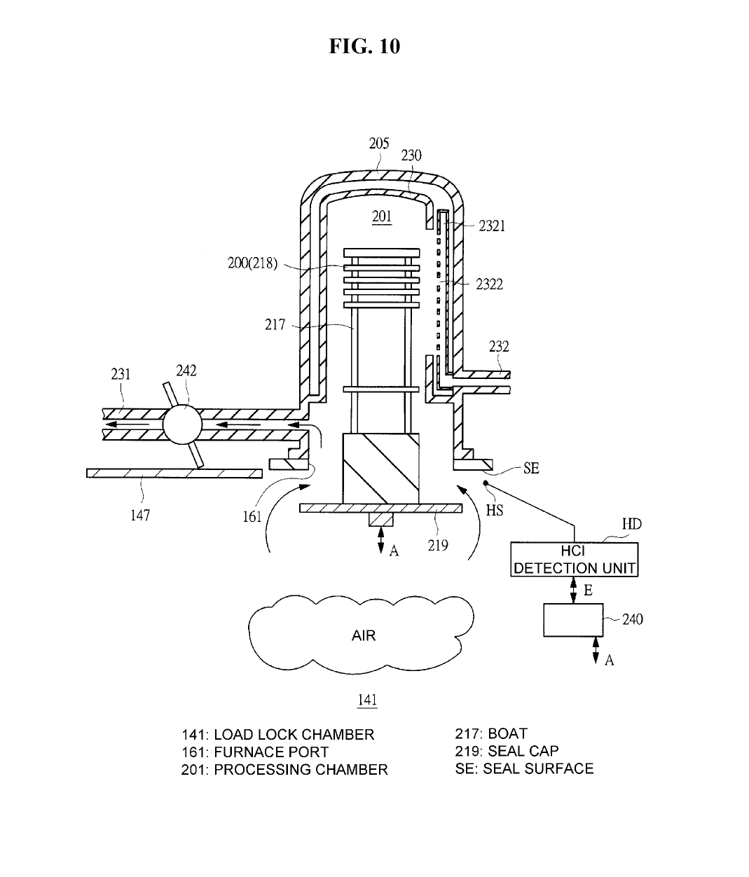

For this reason, in the first embodiment, as illustrated in FIG. 10, after the film-forming process illustrated in FIG. 9 is completed, the seal cap 219, on which the boat 217 is held, is lowered to and held at a position where it slightly moves down from the seal surface SE of the furnace port 161. That is, the seal cap 219 holding the boat 217 is lowered by the control of the controller 240, and is held at the position where it slightly moves down from the seal surface SE of the furnace port 161. Thereby, a gap is defined between the seal surface SE of the furnace port 161 and the seal cap 219, and the air is mixed into the processing chamber 201 through the gap. The APC valve 242 is opened to exhaust the atmosphere in the processing chamber 201 through the gas exhaust pipe 231. In this manner, in the first embodiment, since the atmosphere in the processing chamber 201 is exhausted through the gas exhaust pipe 231, the pressure in the processing chamber 201 reaches a pressure lower than the pressure of the load lock chamber 141. Thus, the air in the load lock chamber 141 flows into the processing chamber 201 through the gap defined between the seal surface SE and the seal cap 219. Thereafter, the air flowing into the processing chamber 201 is exhausted through the gas exhaust pipe 231. As described above, in the first embodiment, a unidirectional flow of the air can be formed in the order of the load lock chamber 141, the gap between the seal surface SE and the seal cap 219, the inside of the processing chamber 201, and the gas exhaust pipe 231. In other words, in the first embodiment, even when the gap is defined between the seal surface SE and the seal cap 219, a backflow from the inside of the processing chamber 201 to the load lock chamber 141 can be prevented.

Here, the air, which flows from the load lock chamber 141 into the processing chamber 201 via the gap between the seal surface SE and the seal cap 219, is subjected to a hydrolytic reaction with the chlorosilane polymer adhered to the inside of the processing chamber 201. Thereby, the chlorosilane polymer is changed into a high-combustible hydrolysate, and hydrogen chloride gas is generated. In the first embodiment, since the unidirectional flow having the order of the load lock chamber 141, the processing chamber 201, and the gas exhaust pipe 231 is formed, the hydrogen chloride gas generated from the inside of the processing chamber 201 hardly flows back to the load lock chamber 141, and is discharged to an outside through the gas exhaust pipe 231. Thus, according to the first embodiment, since the hydrogen chloride gas generated from the inside of the processing chamber 201 can be prevented from flowing back to the load lock chamber 141 through the furnace port 161, the corrosion of the furnace port 161 itself and the corrosion of the load lock chamber 141, both of which are caused by the hydrogen chloride gas, can be prevented.

In the first embodiment, the high-combustible hydrolysate is also formed from the chlorosilane polymer. However, in the first embodiment, the unidirectional flow of the air continues to be formed in the order of the load lock chamber 141, the gap between the seal surface SE and the seal cap 219, the inside of the processing chamber 201, and the gas exhaust pipe 231. For this reason, the moisture contained in the air continues to react with the chlorosilane polymer adhered to the inside of the processing chamber 201, so that the chlorosilane polymer is changed into siloxane that is a stable material. That is, in the first embodiment, the deposited chlorosilane polymer continues to positively react with the air, so that the chlorosilane polymer is changed not into the high-combustible hydrolysate that is an intermediate product, but into the siloxane that is a final product and a stable material. As a result, according to the first embodiment, the high-combustible hydrolysate can be prevented from being deposited in the processing chamber 201. Thus, according to the first embodiment, a problem that the high-combustible hydrolysate is abruptly burnt by impact or static electricity during maintenance can be overcome.

When the chlorosilane polymer adhered to the inside of the processing chamber 201 sufficiently reacts with the moisture, the chlorosilane polymer itself reacting with the moisture is removed. As a result, an amount of the generated hydrogen chloride gas is reduced. As such, in the first embodiment, the sensor HS configured to detect the hydrogen chloride gas is installed adjacent to the furnace port 161, and the HCl detection unit HD configured to detect the concentration level of the hydrogen chloride gas from the output of the sensor HS is installed. Thereby, in the first embodiment, when the concentration level of the hydrogen chloride gas which is detected by the HCl detection unit HD is equal to or higher than a preset concentration level (e.g., 2 ppm), the atmosphere in the processing chamber 201 continues to be exhausted through the gas exhaust pipe 231 under the control of the controller 240, and the seal cap 219 continues to be held at the position where it slightly moves down from the seal surface SE of the furnace port 161. As a result, the air can be allowed to sufficiently react with the chlorosilane polymer adhered to the inside of the processing chamber 201 and the inner wall of the gas exhaust pipe 231.

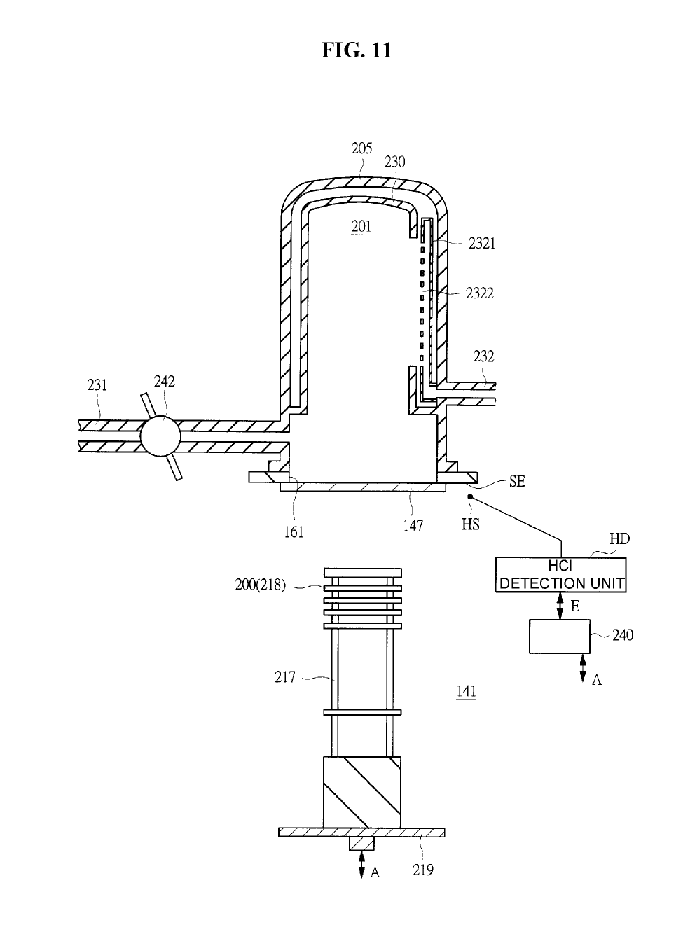

When the concentration level of the hydrogen chloride gas which is detected by the HCl detection unit HD is less than the preset concentration level (e.g., 2 ppm), the controller 240 determines that the chlorosilane polymer adhered to the inside of the processing chamber 201 and the inner wall of the gas exhaust pipe 231 is sufficiently hydrolyzed. Thus, as illustrated in FIG. 11, the seal cap 219 is lowered from the position where it slightly moves down from the seal surface SE of the furnace port 161 to the bottom of the load lock chamber 141 by the control of the controller 240, so that the boat 217 is unloaded from the inside of the processing chamber 201 to the load lock chamber 141 (boat unloading). Thereafter, the processed wafers 200 are taken out from the boat 217 disposed in the load lock chamber 141. Further, the furnace port 161 that is opened at the bottom of the processing chamber 201 is closed by moving the furnace port shutter 147. With the configuration as described above, the substrate processing method according to the first embodiment is performed.

According to the technical idea of the first embodiment, at least one of multiple effects described below is obtained from the configuration as described above.

(1) According to the first embodiment, in the film-forming step, the moisture contained in the air is configured to positively react with the chlorosilane polymer adhered to the inside of the processing chamber 201 and the gas exhaust pipe 231 connected to the processing chamber 201, thereby changing the chlorosilane polymer into the siloxane, which is stable, and generating the hydrogen chloride gas. The generated hydrogen chloride gas is configured to be exhausted through the gas exhaust pipe 231. Thereby, the deposition of the high-combustible hydrolysate and the corrosion caused by the hydrogen chloride gas can be prevented.

(2) In the first embodiment, above all, since the unidirectional flow having the order of the load lock chamber 141, the processing chamber 201, and the gas exhaust pipe 231 is formed, the hydrogen chloride gas generated from the inside of the processing chamber 201 hardly flows back to the load lock chamber 141, and is discharged to the outside through the gas exhaust pipe 231. Thus, according to the first embodiment, since the hydrogen chloride gas generated from the inside of the processing chamber 201 can be prevented from flowing back to the load lock chamber 141 through the furnace port 161, the corrosion of the furnace port 161 itself and the corrosion of the load lock chamber 141, both of which are caused by the hydrogen chloride gas, can be prevented.

(3) In the first embodiment, the sensor HS configured to detect the hydrogen chloride gas and the HCl detection unit HD are provided. Thereby, the hydrogen chloride gas is configured to continue to be exhausted through the gas exhaust pipe 231 until the concentration level of the hydrogen chloride gas is less than the preset concentration level (e.g., 2 ppm). For this reason, the concentration level of the hydrogen chloride gas in the processing chamber 201 can be reliably set to be equal to or lower than the preset concentration level, and to improve safety.

(4) According to the first embodiment, since the chlorosilane polymer is removed by hydrolysis, the deposition of an adherent made up of the chlorosilane polymer can be prevented. As a result, particles or contaminants can be prevented from being adhered to the wafers 200 used in the next film-forming process.

(5) According to the first embodiment, the moisture contained in the air is configured to positively react with the chlorosilane polymer adhered to the inside of the processing chamber 201 and the gas exhaust pipe 231 connected to the processing chamber 201 in the boat unloading process immediately after the film-forming step. Here, since the chlorosilane polymer formed in the film-forming step is in an active state, the moisture in the air positively reacts with the chlorosilane polymer that is in the active state in the boat unloading process immediately after the film-forming step. Thereby, the chlorosilane polymer can be efficiently hydrolyzed to be changed into the siloxane, which is stable.

(6) According to the first embodiment, since the boat unloading process is configured to be used, and the moisture contained in the air is configured to positively react with the chlorosilane polymer adhered to the inside of the processing chamber 201 and the gas exhaust pipe 231 connected to the processing chamber 201, complication of the substrate processing processes can be prevented. That is, in the first embodiment, since a cleaning process of reacting the moisture in the air with the chlorosilane polymer to decompose the chlorosilane polymer is incorporated into the substrate processing apparatus as a part of a film-forming sequence, the cleaning process (characteristic process) can be performed without damaging a driving state of the substrate processing apparatus. In other words, in the first embodiment, since the cleaning process is not performed after the driving state of the substrate processing apparatus is stopped, the cleaning process can be performed without sharply reducing throughput of the substrate processing apparatus.

(7) In the first embodiment, the gap is configured to be formed between the seal surface SE and the seal cap 219, and the air is configured to be introduced into the processing chamber 201 through the gap. That is, since the air can be introduced into the processing chamber 201 through the entire inner circumferential part (furnace port 161) of the processing chamber 201, the moisture contained in the air can be allowed to react with the chlorosilane polymer adhered to the entire inner wall of the processing chamber 201. As a result, the chlorosilane polymer can be changed into the siloxane, which is stable, throughout the inner wall of the processing chamber 201, and the hydrogen chloride gas can be sufficiently generated and exhausted, thereby sufficiently improving safety.

Finally, the technical idea of the first embodiment is arranged as follows. That is, the substrate processing apparatus according to the first embodiment includes the processing chamber 201 that processes the wafers 200 as the substrates, the gas supply pipe 232 as the gas supply unit configured to supply a film-forming gas to the processing chamber 201, and the gap between the seal surface SE and the seal cap 219 which is the opening configured to introduce the air into the processing chamber 201. The substrate processing apparatus further includes the gas exhaust pipe 231 as the exhaust line that is connected to the processing chamber 201 and exhausts the atmosphere of the processing chamber 201, and the controller 240 as the control unit configured to control the supply of the film-forming gas performed by the gas supply pipe 232 as the gas supply unit, the exhaust of the atmosphere performed by the gas exhaust pipe 231 as the exhaust line, and the introduction of the air through the gap as the opening. Here, the controller 240, the control unit, controls the operation of the substrate processing apparatus so as to form the film on the wafer 200 as the substrate in the processing chamber 201. After the film is formed, the controller 240 serving as the control unit controls the operation of the substrate processing apparatus so as to introduce the air into the processing chamber 201 through the gap as the opening, to cause the moisture contained in the air to react with the chlorosilane polymer as the adherent adhered to the inside of the processing chamber 201 and the inside of the gas exhaust pipe 231 as the exhaust line to at least generate the hydrogen chloride gas, and to exhaust and maintain the hydrogen chloride gas through the gas exhaust pipe 231 as the exhaust line until the concentration level of the hydrogen chloride gas in the processing chamber 201 is equal to or lower than a preset concentration level.

Further, the substrate processing method according to the first embodiment includes a first step (or a film-forming step) of forming a film on the wafer 200 as the substrate in the processing chamber 201, and a second step (or a characteristic process) of, after the first step, introducing air from the outside into the inside of the processing chamber 201, causing moisture contained in the air to react with chlorosilane polymer as an adherent adhered to the inside of the processing chamber 201 and the inside of the gas exhaust pipe 231 as the exhaust line connected to the processing chamber 201 to at least generate hydrogen chloride gas, and exhausting the hydrogen chloride gas through the gas exhaust pipe 231 as the exhaust line. The second step is preferably maintained until a concentration level of the hydrogen chloride gas in the processing chamber 201 is equal to or lower than a preset concentration level.

In the first embodiment, a process (or a characteristic process) of causing the moisture contained in the air to positively react with the chlorosilane polymer adhered to the inside of the processing chamber 201 and the gas exhaust pipe 231 connected to the processing chamber 201 in the boat unloading process immediately after the film-forming process is also performed. Here, the film-forming process is repeated as in the substrate processing processes of the film-forming process, the boat unloading process, the boat loading process, the film-forming process, and the boat unloading process. It is particularly preferable that, whenever the plurality of film-forming processes are performed, the characteristic process is repetitively performed in the boat unloading process immediately after the film-forming process. This is because the chlorosilane polymer is adhered to the inside of the processing chamber 201 and the inner wall of the gas exhaust pipe 231 whenever the film-forming process is performed, but the formed chlorosilane polymer is in an active state immediately after the film-forming process. That is, when the chlorosilane polymer is in the active state, the hydrolytic reaction with the moisture is efficiently advanced. As such, the characteristic process is performed in the boat unloading process immediately after the film-forming process in which the chlorosilane polymer is in the active state. Thereby, the chlorosilane polymer into the siloxane may be efficiently hydrolyzed.

### Second Embodiment

The first embodiment has been configured to cause the moisture contained in the air to positively react with the chlorosilane polymer adhered to the inside of the processing chamber 201 and the gas exhaust pipe 231 connected to the processing chamber 201 in the boat unloading process immediately after the film-forming process. However, the second embodiment is configured to cause the moisture contained in the air to positively react with the chlorosilane polymer adhered to the inside of the processing chamber 201 and the gas exhaust pipe 231 connected to the processing chamber 201 in the standby process of charging a new wafer into the boat aside from the wafer 200 on which the film is formed after the boat unloading process is performed immediately after the film-forming process or in the boat loading process performed after the standby process, and this example will be described.

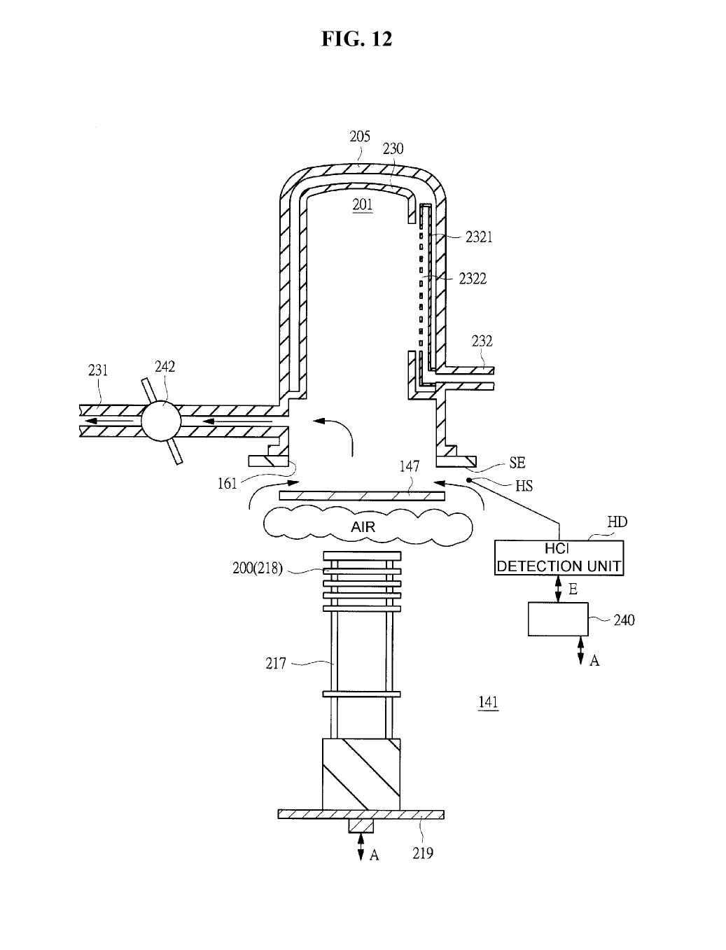

FIG. 12 illustrates a shape in a standby process according to a second embodiment. In FIG. 12, a boat 217 is disposed in a load lock chamber 141, and a new wafer 200 is charged into the boat 217. Here, the furnace port 161 of a processing chamber 201 disposed above the load lock chamber 141 is closed by a furnace port shutter 147. The furnace port shutter 147 is typically disposed so as to come in close contact with a seal surface SE of the furnace port 161. However, in the second embodiment, as illustrated in FIG. 12, a gap is intentionally provided between the seal surface SE and the furnace port shutter 147. For this reason, in the second embodiment, air is mixed into the processing chamber 201 through the gap. An APC valve 242 is opened to exhaust an atmosphere in the processing chamber 201 through a gas exhaust pipe 231. In the second embodiment, since the atmosphere in the processing chamber 201 is exhausted through a gas exhaust pipe 231, the pressure in the processing chamber 201 is lower than that of the load lock chamber 141. Thus, the air existing in the load lock chamber 141 flows into the processing chamber 201 through the gap defined between the seal surface SE and a seal cap 219. Thereafter, the air flowing into the processing chamber 201 is exhausted through the gas exhaust pipe 231. As described above, in the second embodiment, a unidirectional flow of the air can be formed in the order of the load lock chamber 141, the gap between the seal surface SE and the furnace port shutter 147, the inside of the processing chamber 201, and the gas exhaust pipe 231. In other words, in the second embodiment, even when the gap is defined between the seal surface SE and the furnace port shutter 147, a backflow from the inside of the processing chamber 201 to the load lock chamber 141 can be prevented.

Here, the air, which flows from the load lock chamber 141 into the processing chamber 201 via the gap between the seal surface SE and the furnace port shutter 147, is subjected to a hydrolytic reaction with chlorosilane polymer adhered to the inside of the processing chamber 201. Thereby, the chlorosilane polymer is changed into a high-combustible hydrolysate, and hydrogen chloride gas is generated. In the second embodiment, since the unidirectional flow having the order of the load lock chamber 141, the processing chamber 201, and the gas exhaust pipe 231 is formed, the hydrogen chloride gas generated from the inside of the processing chamber 201 hardly flows back to the load lock chamber 141, and is discharged to an outside through the gas exhaust pipe 231. Thus, according to the second embodiment, since the hydrogen chloride gas generated from the inside of the processing chamber 201 from flowing back to the load lock chamber 141 through the furnace port 161 can be prevented, the corrosion of the furnace port 161 itself and the corrosion of the load lock chamber 141, both of which are caused by the hydrogen chloride gas, can be prevented.

In the second embodiment, the high-combustible hydrolysate is also formed from the chlorosilane polymer. However, in the second embodiment, the unidirectional flow of the air continues to be formed in the order of the load lock chamber 141, the gap between the seal surface SE and the furnace port shutter 147, the inside of the processing chamber 201, and the gas exhaust pipe 231. For this reason, moisture contained in the air continues to react with the chlorosilane polymer adhered to the inside of the processing chamber 201, so that the chlorosilane polymer is changed into siloxane that is a stable material. That is, in the second embodiment, the deposited chlorosilane polymer continues to positively react with the air, so that the chlorosilane polymer is changed into, not the high-combustible hydrolysate that is an intermediate product, but the siloxane that is a final product and a stable material. As a result, according to the second embodiment, the high-combustible hydrolysate can be prevented from being deposited in the processing chamber 201. Thus, according to the second embodiment, a problem that the high-combustible hydrolysate is abruptly burnt by impact or static electricity during the maintenance can be overcome.

Further, in the second embodiment, a sensor HS configured to detect the hydrogen chloride gas and a HCl detection unit HD are installed. Thereby, the hydrogen chloride gas is configured to continue to be exhausted through the gas exhaust pipe 231 until a concentration level of the hydrogen chloride gas reaches or is lower than a preset concentration level (e.g., 2 ppm). For this reason, the concentration level of the hydrogen chloride gas in the processing chamber 201 can be reliably set to be equal to or lower than the preset concentration level, and to improve safety. With the configuration as described above, the standby process in the second embodiment is terminated.

Subsequently, when the standby process is terminated, a boat loading process of loading the boat 217 into the processing chamber 201 is performed. Here, as described above, in the standby process, the characteristic process of causing the chlorosilane polymer adhered to the inside of the processing chamber 201 and the gas exhaust pipe 231 connected to the processing chamber 201 to positively react with the moisture contained in the air is performed. However, the characteristic process may be performed in the boat loading process which will be described below, rather than in the standby process. Hereinafter, an example of performing the characteristic process in the boat loading process will be described.

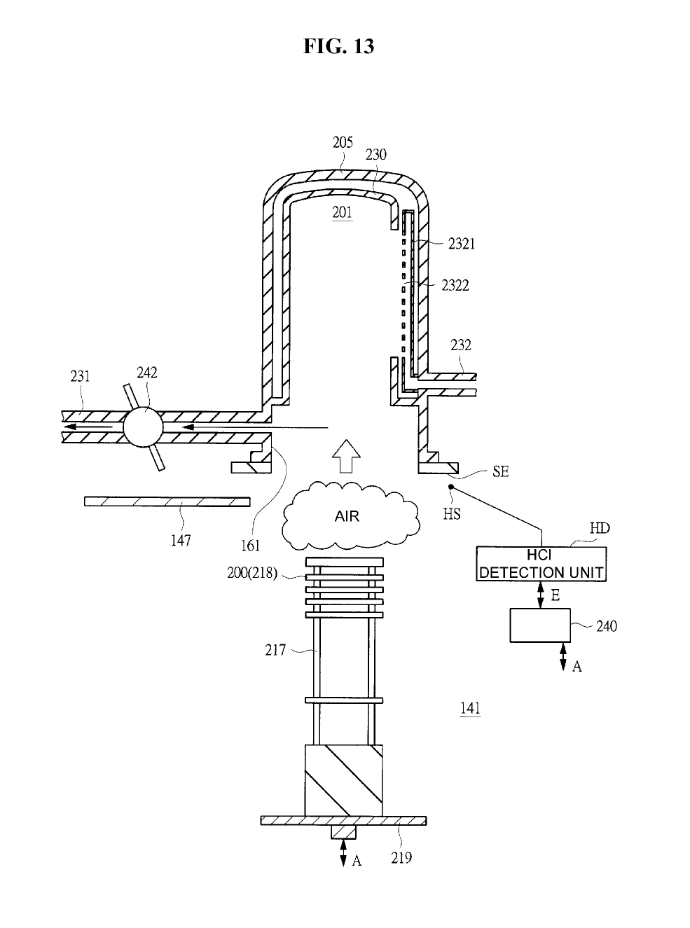

FIG. 13 illustrates a shape in a boat loading process according to the second embodiment. In FIG. 13, the boat 217 is disposed in the load lock chamber 141. Here, the furnace port shutter 147, which closes the furnace port 161 of the processing chamber 201 in the standby process, is kept open, and the furnace port 161 is opened. Thus, air is mixed into the processing chamber 201 through the open furnace port 161. The APC valve 242 is opened to exhaust an atmosphere in the processing chamber 201 through the gas exhaust pipe 231. Accordingly, the air existing in the load lock chamber 141 is mixed into the processing chamber 201 through the open furnace port 161. Thereafter, the air flowing into the processing chamber 201 is exhausted through the gas exhaust pipe 231. As described above, in the second embodiment, the unidirectional flow of the air can be formed in the order of the load lock chamber 141, the open furnace port 161, the inside of the processing chamber 201, and the gas exhaust pipe 231.

Here, the air, which flows from the load lock chamber 141 into the processing chamber 201 via the open furnace port 161, is subjected to a hydrolytic reaction with chlorosilane polymer adhered to the inside of the processing chamber 201. Thereby, the chlorosilane polymer is changed into a high-combustible hydrolysate, and hydrogen chloride gas is generated. In the second embodiment, since the unidirectional flow having the order of the load lock chamber 141, the processing chamber 201, and the gas exhaust pipe 231 is formed, the hydrogen chloride gas generated from the inside of the processing chamber 201 hardly flows back to the load lock chamber 141, and is discharged to an outside through the gas exhaust pipe 231. Thus, according to the second embodiment, since the hydrogen chloride gas generated from the inside of the processing chamber 201 can be prevented from flowing back to the load lock chamber 141 through the furnace port 161, the corrosion of the furnace port 161 itself and the corrosion of the load lock chamber 141, both of which are caused by the hydrogen chloride gas, can be prevented.

In the second embodiment, the high-combustible hydrolysate is also formed from the chlorosilane polymer. However, in the second embodiment, the unidirectional flow of the air continues to be formed in the order of the load lock chamber 141, the open furnace port 161, the inside of the processing chamber 201, and the gas exhaust pipe 231. For this reason, moisture contained in the air continues to react with the chlorosilane polymer adhered to the inside of the processing chamber 201, so that the chlorosilane polymer is changed into siloxane that is a stable material. That is, in the second embodiment, the deposited chlorosilane polymer continues to positively react with the air, so that the chlorosilane polymer is changed into, not the high-combustible hydrolysate that is an intermediate product, but the siloxane that is a final product and a stable material. As a result, according to the second embodiment, the high-combustible hydrolysate can be prevented from being deposited in the processing chamber 201. Thus, according to the second embodiment, a problem that the high-combustible hydrolysate is abruptly burnt by impact or static electricity during the maintenance can be overcome.

Further, in the second embodiment, the sensor HS configured to detect the hydrogen chloride gas and the HCl detection unit HD are installed. Thereby, the hydrogen chloride gas is configured to continue to be exhausted through the gas exhaust pipe 231 until a concentration level of the hydrogen chloride gas reaches or is lower than a preset concentration level (e.g., 2 ppm). For this reason, the concentration level of the hydrogen chloride gas in the processing chamber 201 can be reliably set to be equal to or lower than a preset concentration level, and to improve safety.

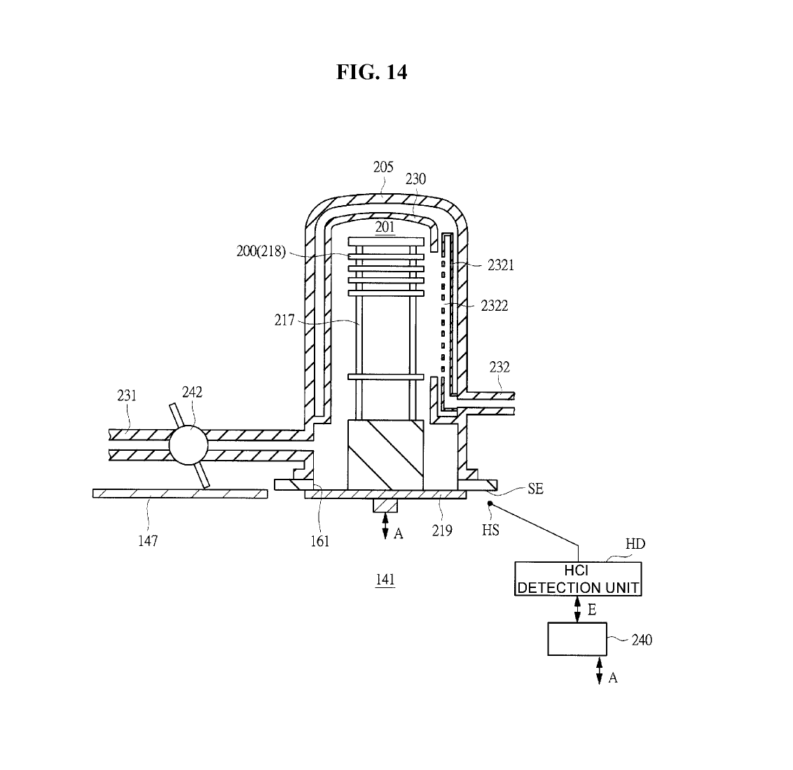

Thereafter, as illustrated in FIG. 14, the seal cap 219 on which the boat 217 is held is elevated by the control of the controller 240. Thereby, the boat 217 is loaded into the processing chamber 201. Here, the processing chamber 201 is sealed by bringing the seal cap 219 into contact with the seal surface SE of the furnace port 161. With the configuration as described above, the boat loading process in the second embodiment is terminated. Thereafter, film forming is performed on the wafers 200 held on the boat 217.

In the first embodiment, the example of performing the characteristic process in the boat unloading process immediately after the film-forming process has been described. In the second embodiment, the example of performing the characteristic process in the new standby process after the boat unloading process or in the boat loading process has been described. The technical idea of the present invention is not limited to these embodiments. For example, the characteristic process may be performed by a combination of the first embodiment and the second embodiment.

In this case, a time for which the air is introduced from the outside of the processing chamber 201 into the inside of the processing chamber 201 in the boat unloading process (first embodiment) is preferably set to be longer than that for which the air is introduced from the outside of the processing chamber 201 into the inside of the processing chamber 201 in the boat loading process (second embodiment). This is because the formed chlorosilane polymer is in an active state immediately after the film-forming process. That is, the chlorosilane polymer adhered to the processing chamber 201 is in a more active state in the boat unloading process immediately after the film-forming process rather than in the boat loading process where a predetermined time has elapsed from the film-forming process. When the chlorosilane polymer is in the active state, the hydrolytic reaction with the moisture is efficiently advanced. As such, when the time for which the air is introduced is sufficiently increased in the boat unloading process immediately after the film-forming process in which the chlorosilane polymer is in the active state, the moisture undergoing the hydrolytic reaction with the chlorosilane polymer that is in the active state can be sufficiently supplied. That is, when the moisture is sufficiently supplied to the chlorosilane polymer that is in the active state, the chlorosilane polymer can be efficiently hydrolyzed to be changed into the siloxane that is the stable material. This means that, when the air is configured to be sufficiently introduced in the boat unloading process rather than in the boat loading process, the hydrolysis of the chlorosilane polymer can be efficiently performed because the chlorosilane polymer is in the active state, and the characteristic process (cleaning process) can be efficiently performed. As described above, when the time for which the air is introduced from the outside of the processing chamber 201 into the inside of the processing chamber 201 in the boat unloading process is set to be longer than that for which the air is introduced from the outside of the processing chamber 201 into the inside of the processing chamber 201 in the boat loading process, the efficiency of a series of film-forming sequences including the characteristic process performed by the substrate processing apparatus can be promoted, and throughput can be improved.

### Third Embodiment

In the third embodiment, the substrate processing apparatus having an air supply pipe 233 serving as an air supply unit that is connected to a processing chamber 201 and a valve V1 configured to adjust a flow rate of air flowing through the air supply pipe 233 will be described.

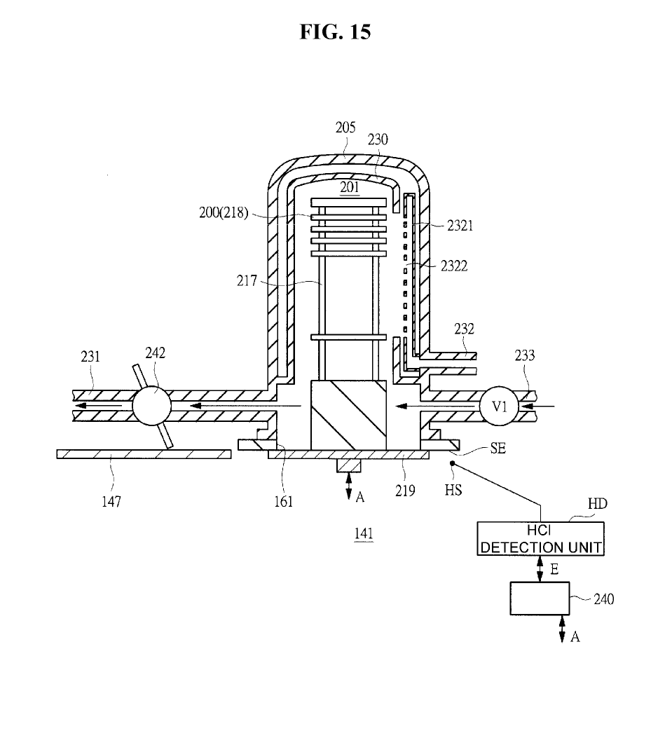

FIG. 15 is a diagram illustrating a configuration of the surroundings of the processing chamber 201 of the substrate processing apparatus according to the third embodiment. Since the configuration of the substrate processing apparatus according to the third embodiment illustrated in FIG. 15 is nearly the same as the configuration of the substrate processing apparatus according to the first embodiment illustrated in FIG. 9, a difference between the third embodiment and the first embodiment will be described in detail.

As can be seen from the comparison of FIG. 9 with FIG. 15, in the substrate processing apparatus according to the third embodiment, an air supply pipe 233 connected to a processing chamber 201 is provided, and a valve V1 is installed on the air supply pipe 233. The valve V1 is configured so that opening and closing of the valve V1 can be controlled by a controller 240. In the substrate processing apparatus according to the third embodiment configured in this way, air can be supplied into the processing chamber 201 through the air supply pipe 233 with the seal surface SE of a furnace port 161 closed by a seal cap 219. Even when no gap is provided between the seal cap 219 and the seal surface SE of the furnace port 161, the air can be introduced into the processing chamber 201.

Hereinafter, the characteristic process of the substrate processing method according to the third embodiment will be described. In the third embodiment, the characteristic process is performed in the boat unloading process of unloading the boat 217 from the processing chamber 201 after the film forming is completed.

FIG. 15 illustrates a state after the film-forming process. In FIG. 15, in the film-forming process, SiH₂Cl₂ (dichlorosilane) as a source gas is pyrolized and polymerized, so that a by-product such as a chlorosilane polymer is produced. The produced chlorosilane polymer is adhered to and deposited on the inside of the processing chamber 201 and the inner wall of a gas exhaust pipe 231 that is an exhaust line.

Subsequently, in the third embodiment, as illustrated in FIG. 15, after the film-forming process is completed, first, the valve V1 is opened by the control of the controller 240, and air is introduced into the processing chamber 201 through the air supply pipe 233. Further, an APC valve 242 is opened to exhaust an atmosphere in the processing chamber 201 through a gas exhaust pipe 231. Thereby, in the third embodiment, a unidirectional flow of the air can be formed in the order of the air supply pipe 233, the inside of the processing chamber 201, and the gas exhaust pipe 231.

Here, the air, which flows into the processing chamber 201 via the air supply pipe 233, is subjected to a hydrolytic reaction with a chlorosilane polymer adhered to the inside of the processing chamber 201. Thereby, the chlorosilane polymer is changed into a high-combustible hydrolysate, and hydrogen chloride gas is generated. In the third embodiment, since the unidirectional flow having the order of the air supply pipe 233, the processing chamber 201, and the gas exhaust pipe 231 is formed, the hydrogen chloride gas generated from the inside of the processing chamber 201 is discharged to the outside through the gas exhaust pipe 231. Thus, the third embodiment has an advantage in that no gap is provided between the seal cap 219 and the seal surface SE of the furnace port 161 in order to introduce the air into the processing chamber 201. For example, when a gap is provided between the seal cap 219 and the seal surface SE of the furnace port 161, the processing chamber 201 is connected with a load lock chamber 141. In this case, there is a possibility of the hydrogen chloride gas generated from the inside of the processing chamber 201 flowing back to the load lock chamber 141.

With regard to this problem, the third embodiment is configured so that the seal cap 219 is brought into close contact with the seal surface SE of the furnace port 161 with no gap provided between the seal cap 219 and the seal surface SE of the furnace port 161. For this reason, there is an advantage in that the possibility of the hydrogen chloride gas generated from the inside of the processing chamber 201 flowing to the load lock chamber 141 can be further reduced. According to the third embodiment, since the hydrogen chloride gas generated from the inside of the processing chamber 201 can be prevented from flowing back to the load lock chamber 141, the corrosion of the load lock chamber 141 which is caused by the hydrogen chloride gas can be effectively prevented.

In the third embodiment, the high-combustible hydrolysate is also formed from the chlorosilane polymer. However, in the third embodiment, the unidirectional flow of the air continues to be formed in the order of the air supply pipe 233, the inside of the processing chamber 201, and the gas exhaust pipe 231. For this reason, moisture contained in the air continues to react with the chlorosilane polymer adhered to the inside of the processing chamber 201, so that the chlorosilane polymer is changed into siloxane that is a stable material. That is, in the third embodiment, the deposited chlorosilane polymer continues to positively react with the air, so that the chlorosilane polymer is changed into, not the high-combustible hydrolysate that is an intermediate product, but the siloxane that is a final product and a stable material. As a result, according to the third embodiment, the high-combustible hydrolysate can be prevented from being deposited in the processing chamber 201. Thus, according to the third embodiment, a problem that the high-combustible hydrolysate is abruptly burnt by impact or static electricity during the maintenance can be overcome.

Further, in the third embodiment, a sensor HS configured to detect the hydrogen chloride gas and an HCl detection unit HD are installed. Thereby, the third embodiment is configured so that, after the air continues to be supplied into the processing chamber 201 through the air supply pipe 233 for a predetermined time, a gap is provided between the seal cap 219 and the seal surface SE of the furnace port 161, and it is detected whether a concentration level of the hydrogen chloride gas reaches or is lower than a preset concentration level (e.g., 2 ppm). When the concentration level of the hydrogen chloride gas is not less than the preset concentration, the hydrogen chloride gas is configured to continue to be exhausted through the gas exhaust pipe 231 until the concentration level of the hydrogen chloride gas reaches the preset concentration level. For this reason, the concentration level of the hydrogen chloride gas in the processing chamber 201 can be reliably set to be equal to or lower than a preset concentration level, and to improve safety.

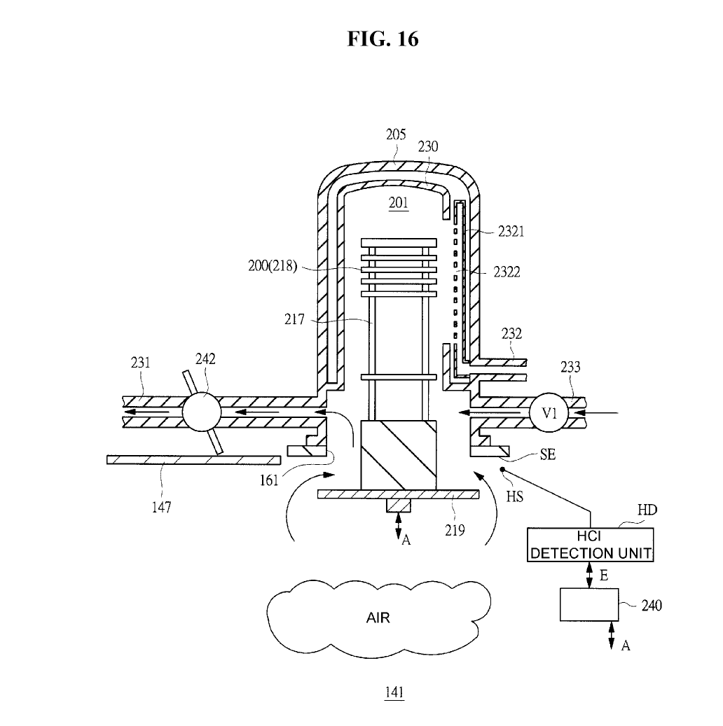

Further, a characteristic process in the third embodiment is performed, for instance, in a boat unloading process of unloading a boat 217 from the processing chamber 201 after film forming is completed, as illustrated in FIG. 15. However, in the boat unloading process, the characteristic process may, for instance, be performed with the configuration as illustrated in FIG. 16.

In the example illustrated in FIG. 16, a flow of the air is formed in the order of the air supply pipe 233, the inside of the processing chamber 201, and the gas exhaust pipe 231, and the flow of the air is also formed in the order of the load lock chamber 141, the gap between the seal surface SE and the seal cap 219, the inside of the processing chamber 201, and the gas exhaust pipe 231. That is, in the example illustrated in FIG. 16, the air is introduced into the processing chamber 201 through the air supply pipe 233, and the air is also introduced from the load lock chamber 141 into the processing chamber 201 via the gap between the seal surface SE and the seal cap 219. Thereby, an amount of supply of the air introduced into the processing chamber 201 can be increased.

As described above, the formed the chlorosilane polymer is in an active state immediately after the film-forming process. When the chlorosilane polymer is in the active state, the hydrolytic reaction with the moisture is efficiently advanced. As such, in the boat unloading process immediately after the film-forming process in which the chlorosilane polymer is in the active state, an amount of air introduced into the processing chamber 201 is increased as in the example illustrated in FIG. 16. Thereby, the chlorosilane polymer can be efficiently hydrolyzed into the siloxane.

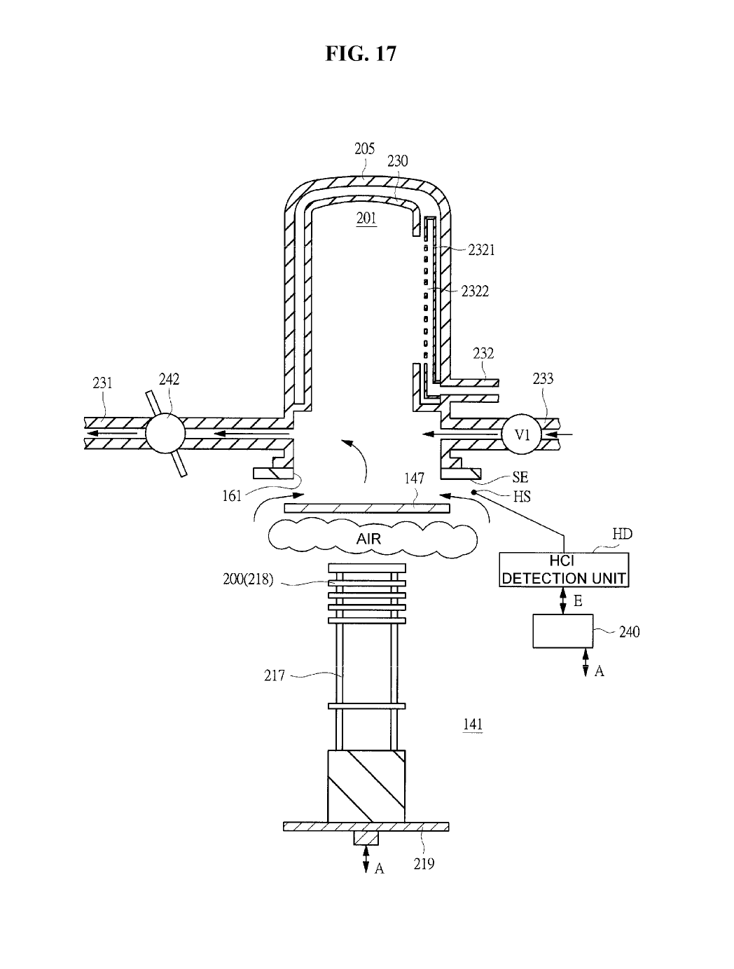

Further, as illustrated in FIG. 17, the characteristic process in the third embodiment may be performed, for instance, in a standby process of charging a new wafer into the boat aside from the wafer 200 undergoing the film forming after the boat unloading process is performed immediately after the film-forming process.

In the example illustrated in FIG. 17, a flow of the air is formed in the order of the air supply pipe 233, the inside of the processing chamber 201, and the gas exhaust pipe 231, and the flow of the air is also formed in the order of the load lock chamber 141, the gap between the seal surface SE and the seal cap 219, the inside of the processing chamber 201, and the gas exhaust pipe 231. That is, in the example illustrated in FIG. 17, the air is introduced into the processing chamber 201 through the air supply pipe 233, and the air is also introduced from the load lock chamber 141 into the processing chamber 201 via the gap between the seal surface SE and the seal cap 219. Thereby, an amount of supply of the air introduced into the processing chamber 201 can be increased.

Further, the characteristic process in the third embodiment may be performed in the boat unloading process that is performed after the standby process.

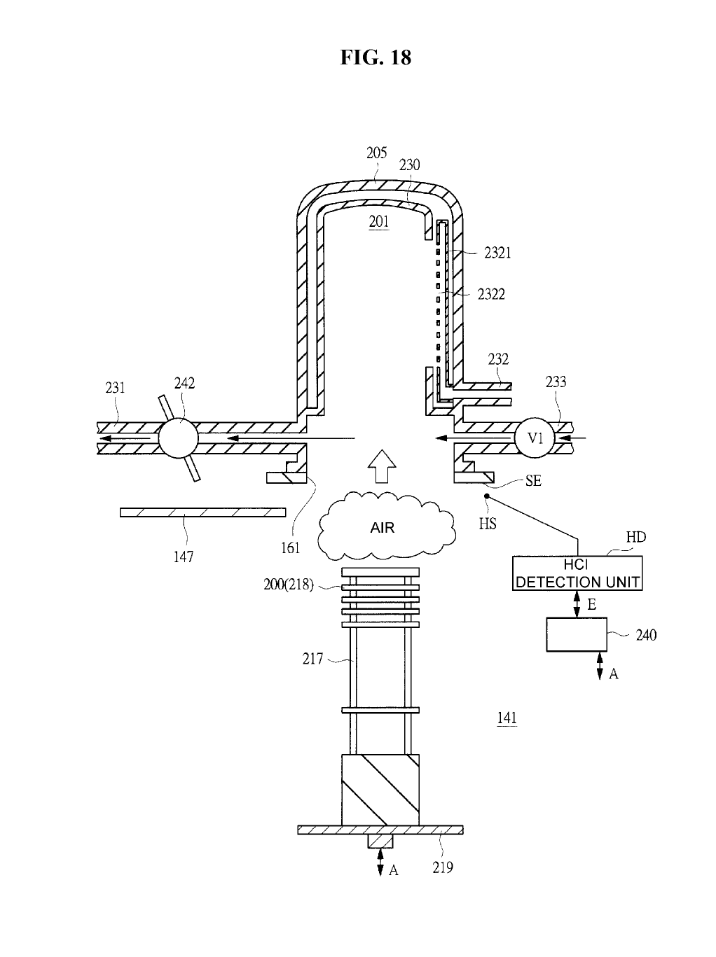

In the example illustrated in FIG. 18, a flow of the air is formed in the order of the air supply pipe 233, the inside of the processing chamber 201, and the gas exhaust pipe 231, and the flow of the air is also formed in the order of the load lock chamber 141, the open furnace port 161, the inside of the processing chamber 201, and the gas exhaust pipe 231. That is, in the example illustrated in FIG. 18, the air is introduced into the processing chamber 201 through the air supply pipe 233, and the air is also introduced from the load lock chamber 141 into the processing chamber 201 via the open furnace port 161. Thereby, an amount of supply of the air introduced into the processing chamber 201 can be increased.

### Fourth Embodiment

In the fourth embodiment, an example of using an inert gas supply unit 186 connected to a gas supply pipe 232 via a valve V2 in a characteristic process will be described.

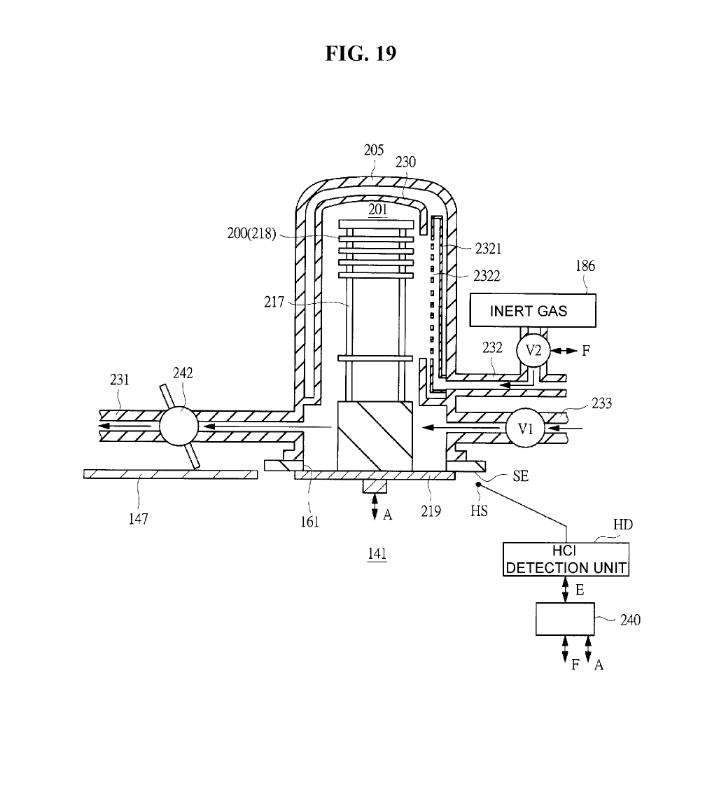

FIG. 19 is a diagram illustrating a configuration of the surroundings of the processing chamber 201 of the substrate processing apparatus according to the fourth embodiment. Since the configuration of the substrate processing apparatus according to the fourth embodiment illustrated in FIG. 19 is nearly the same as the configuration of the substrate processing apparatus according to the third embodiment illustrated in FIG. 15, a difference between the fourth embodiment and the third embodiment will be described in detail.

As can be seen from the comparison of FIG. 15 with FIG. 19, in the substrate processing apparatus according to the fourth embodiment, the inert gas supply unit 186 is installed on the gas supply pipe 232 connected to a processing chamber 201 via the valve V2. The valve V2 is configured so that opening and closing of the valve V2 can be controlled by a controller 240. In the substrate processing apparatus according to the fourth embodiment configured in this way, air can be supplied into the processing chamber 201 through an air supply pipe 233, and an inert gas (e.g., nitrogen gas) can be supplied from the inert gas supply unit 186 into the processing chamber 201 by opening the valve V2.

A typical substrate processing apparatus is configured to supply a source gas into the processing chamber 201 through the gas supply pipe 232 when film forming is performed. After the film forming is completed, the source gas remaining in the processing chamber 201 is replaced with the inert gas. For this reason, in the typical substrate processing apparatus, the inert gas supply unit 186 is installed on the gas supply pipe 232 via the valve V2. In the fourth embodiment, the characteristic process is configured to supply the inert gas from the inert gas supply unit 186 into the processing chamber 201.

Hereinafter, the characteristic process of the substrate processing method according to the fourth embodiment will be described. In the fourth embodiment, the characteristic process is performed in the boat unloading process of unloading the boat 217 from the processing chamber 201 after the film forming is completed.

FIG. 19 is a diagram illustrating a state after the film-forming process. In FIG. 19, in the film-forming process, SiH₂Cl₂ (dichlorosilane) serving as a source gas is pyrolized and polymerized, so that a by-product such as a chlorosilane polymer is produced. The produced chlorosilane polymer is adhered to and deposited on the inside of the processing chamber 201 and the inner wall of a gas exhaust pipe 231 that is an exhaust line.

Subsequently, in the fourth embodiment, as illustrated in FIG. 19, after the film-forming process is completed, first, a valve V1 is opened by the control of the controller 240, thereby introducing air into the processing chamber 201 through an air supply pipe 233. Further, an APC valve 242 is opened by the control of the controller 240, thereby exhausting an atmosphere in the processing chamber 201 through a gas exhaust pipe 231. Thereby, in the fourth embodiment, a unidirectional flow of the air can be formed in the order of the air supply pipe 233, the inside of the processing chamber 201, and the gas exhaust pipe 231. Further, in the fourth embodiment, the valve V2 is opened by the control of the controller 240, and an inert gas is mixed into the processing chamber 201 through the gas supply pipe 232. In this characteristic process of the fourth embodiment, the air introduced through the air supply pipe 233 and the inert gas introduced through the gas supply pipe 232 are present in the processing chamber 201 in a mixed state. An amount of the inert gas supplied into the processing chamber 201 can be adjusted by a controller 240 controlling a degree of opening of the valve V2. This means that, when the amount of inert gas supplied into the processing chamber 201 is adjusted, an amount of the air introduced through the air supply pipe 233 can be indirectly adjusted. The fourth embodiment is characterized in that, in the characteristic process, an amount of introduction of the air is indirectly adjusted by adjusting an amount of supply of the inert gas.

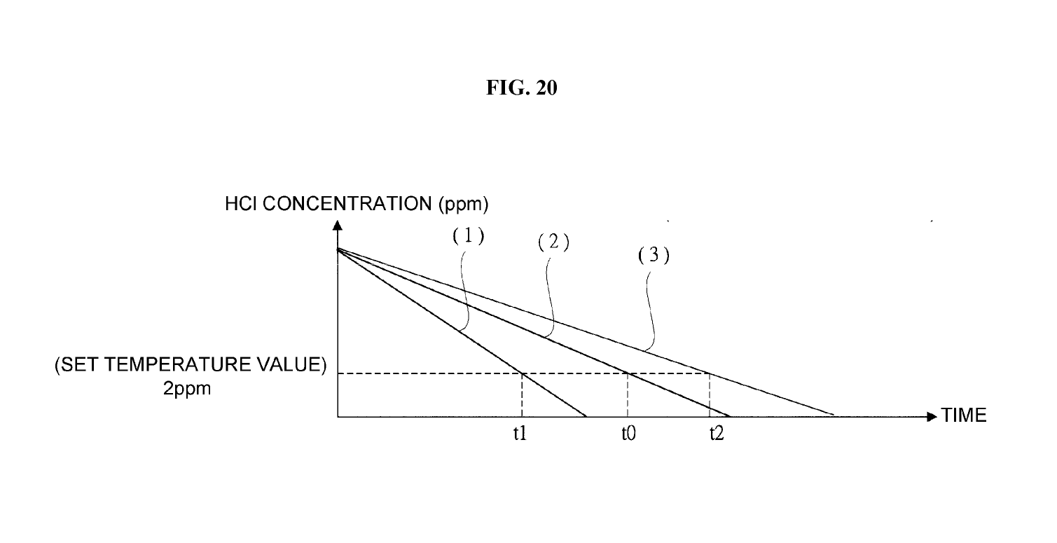

For example, FIG. 20 is a graph showing a change in concentration of hydrogen chloride gas (HCl concentration) generated from the inside of the processing chamber 201 over time. In FIG. 20, the axis of abscissa denotes a time, and the axis of ordinate denotes a concentration (ppm) of the hydrogen chloride gas in the processing chamber 201.

First, graph (1) shown in FIG. 20 shows a case where the change of concentration level of the hydrogen chloride gas generated from the processing chamber 201 is sharp. That is, in graph (1), the concentration level of the hydrogen chloride gas of the processing chamber 201 reaches a level lower than a preset concentration level (e.g., 2 ppm) at time t1. Next, graph (2) shown in FIG. 20 shows a case where the change of concentration level of the hydrogen chloride gas generated from the processing chamber 201 is standard. That is, in graph (2), the concentration level of the hydrogen chloride gas of the processing chamber 201 reaches a level lower than a preset concentration level (e.g., 2 ppm) at time t0 (where t0>t1). Subsequently, graph (3) shown in FIG. 20 shows a case where the change of concentration level of the hydrogen chloride gas generated from the processing chamber 201 is slow. That is, in graph (3), the concentration level of the hydrogen chloride gas of the processing chamber 201 reaches a level lower than a preset concentration level (e.g., 2 ppm) at time t2 (where t2>t0>t1).

Here, referring to graph (3), the fact that the change of concentration level of the hydrogen chloride gas generated from the processing chamber 201 is slow means that an amount of a chlorosilane polymer adhered to the inside of the processing chamber 201 is much, and a great deal of hydrogen chloride gas is generated.

As such, in the fourth embodiment, for example, the controller 240 sets a preset time t0, and monitors whether or not a concentration level of the hydrogen chloride gas reaches or is lower than a preset concentration level within the preset time t0. When the concentration level of the hydrogen chloride gas does not reach the preset concentration level within the preset time t0, the controller 240 adjusts the degree of opening of the valve V2, and reduces an amount of the inert gas supplied into the processing chamber 201. As a result, an amount of the air supplied into the processing chamber 201 can be increased. Thereby, a hydrolytic reaction of moisture contained in the air with the chlorosilane polymer adhered to the inside of the processing chamber 201 can be efficiently advanced, and the efficiency of generation of the hydrogen chloride gas can be enhanced. Thus, a great deal of hydrogen chloride gas can be generated and exhausted within a short time. As such, a time that is required until the concentration level of the hydrogen chloride gas reaches the preset concentration level can be reduced.

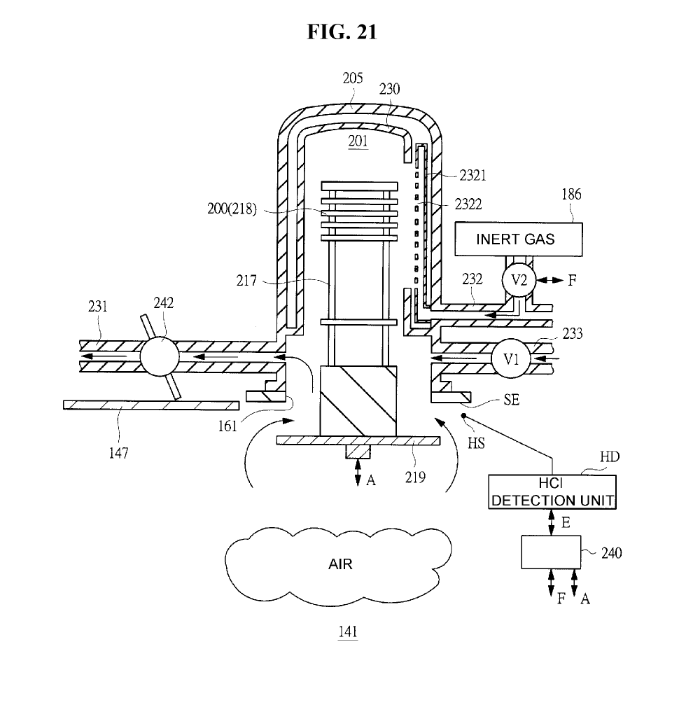

In the fourth embodiment, as illustrated in FIG. 19, the characteristic process is performed, for instance, in the boat unloading process of unloading the boat 217 from the processing chamber 201 after the film forming is completed. In the boat unloading process, the characteristic process may be performed, for instance, as illustrated in FIG. 21.

In the example illustrated in FIG. 21, a flow of the air is formed in the order of the air supply pipe 233, the inside of the processing chamber 201, and the gas exhaust pipe 231, and the flow of the air is also formed in the order of the load lock chamber 141, the gap between the seal surface SE and the seal cap 219, the inside of the processing chamber 201, and the gas exhaust pipe 231. That is, in the example illustrated in FIG. 21, the air is introduced into the processing chamber 201 through the air supply pipe 233, and the air is also introduced from the load lock chamber 141 into the processing chamber 201 via the gap between the seal surface SE and the seal cap 219. In this case, the valve V2 may also be opened by the control of the controller 240, and the inert gas may be mixed into the processing chamber 201 through the gas supply pipe 232. The controller 240 sets a preset time, and monitors whether or not the concentration level of the hydrogen chloride gas reaches the preset concentration level within the preset time. When the concentration level of the hydrogen chloride gas does not reach the preset concentration level within the preset time, the controller 240 may be configured to adjust the degree of opening of the valve V2, and reduce the amount of the inert gas supplied into the processing chamber 201.

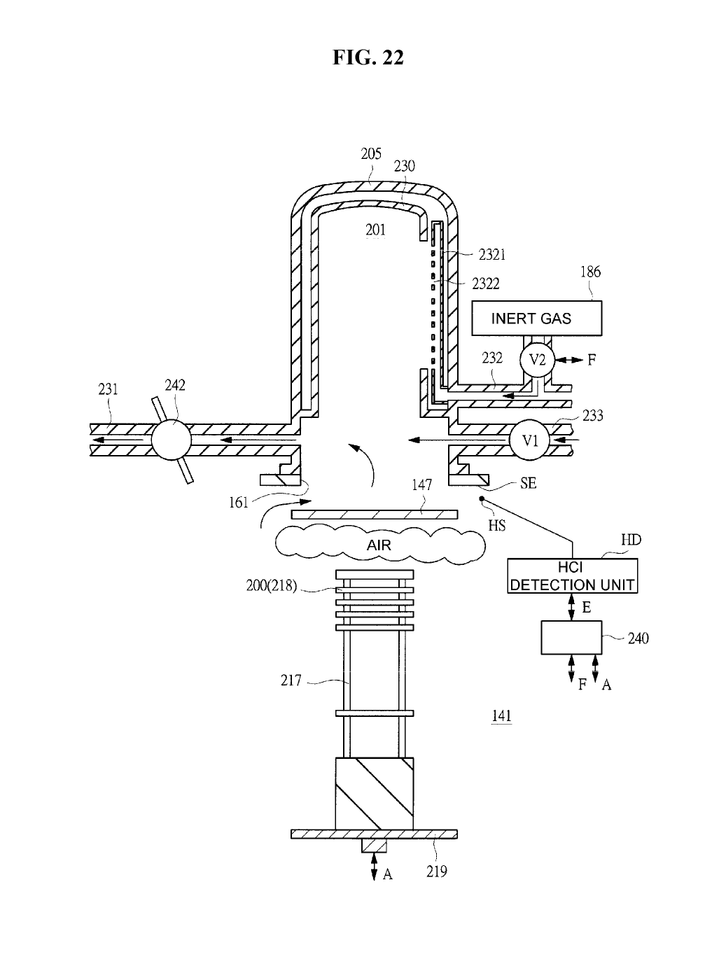

Further, as illustrated in FIG. 22, the characteristic process in the fourth embodiment may be performed, for instance, in a standby process of charging a new wafer into the boat aside from the wafer 200 undergoing the film forming after the boat unloading process is performed immediately after the film-forming process.

In the example illustrated in FIG. 22, a flow of the air is formed in the order of the air supply pipe 233, the inside of the processing chamber 201, and the gas exhaust pipe 231, and the flow of the air is also formed in the order of the load lock chamber 141, the gap between the seal surface SE and the furnace port shutter 147, the inside of the processing chamber 201, and the gas exhaust pipe 231. That is, in the example illustrated in FIG. 22, the air is introduced into the processing chamber 201 through the air supply pipe 233, and the air is also introduced from the load lock chamber 141 into the processing chamber 201 via the gap between the seal surface SE and the furnace port shutter 147. In this case, the valve V2 may also be opened by the control of the controller 240, and the inert gas may be mixed into the processing chamber 201 through the gas supply pipe 232. The controller 240 sets a preset time, and monitors whether or not the concentration level of the hydrogen chloride gas reaches the preset concentration level within the preset time. When the concentration level of the hydrogen chloride gas does not reach the preset concentration level within the preset time, the controller 240 may be configured to adjust the degree of opening of the valve V2, and to reduce the amount of the inert gas supplied into the processing chamber 201.

Further, the characteristic process in the fourth embodiment may be performed in the boat loading process performed after the standby process.

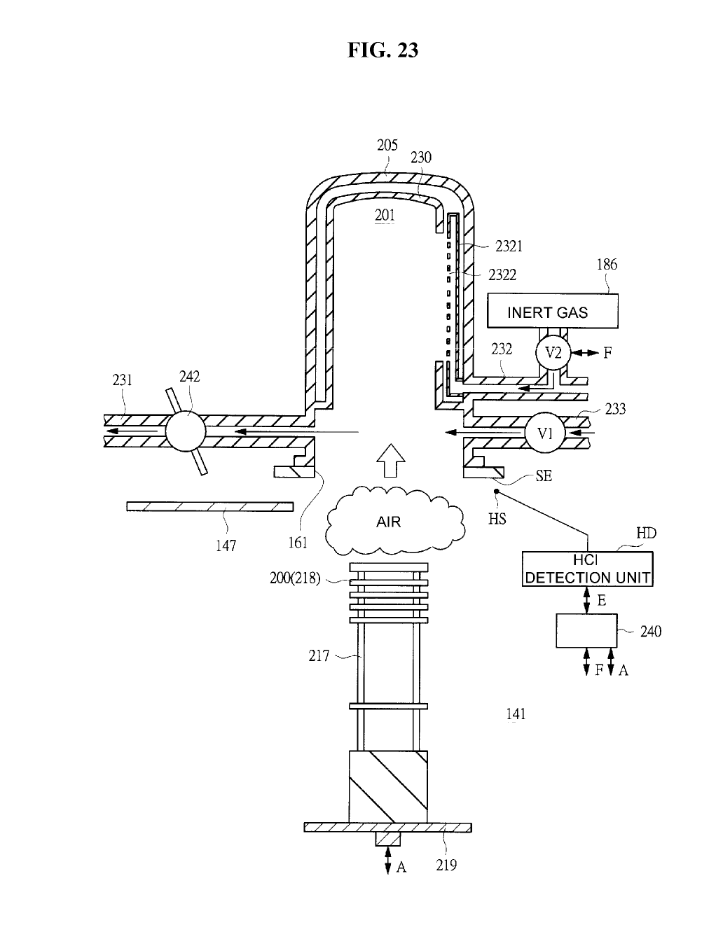

In the example illustrated in FIG. 23, a flow of the air is formed in the order of the air supply pipe 233, the inside of the processing chamber 201, and the gas exhaust pipe 231, and the flow of the air is also formed in the order of the load lock chamber 141, the open furnace port 161, the inside of the processing chamber 201, and the gas exhaust pipe 231. That is, in the example illustrated in FIG. 23, the air is introduced into the processing chamber 201 through the air supply pipe 233, and the air is also introduced from the load lock chamber 141 into the processing chamber 201 via the open furnace port 161. In this case, the valve V2 may also be opened by the control of the controller 240, and the inert gas may be mixed into the processing chamber 201 through the gas supply pipe 232. The controller 240 sets a preset time, and monitors whether or not the concentration level of the hydrogen chloride gas reaches the preset concentration level within the preset time. When the concentration level of the hydrogen chloride gas does not reach the preset concentration level within the preset time, the controller 240 may be configured to adjust the degree of opening of the valve V2, and to reduce the amount of the inert gas supplied into the processing chamber 201.

### Fifth Embodiment

In the fourth embodiment, the example of indirectly adjusting the amount of introduction of the air by adjusting the amount of supply of the inert gas in the characteristic process has been described. However, in the fifth embodiment, an example of adjusting the amount of introduction of the air by adjusting the magnitude of a gap formed between a seal surface SE and a seal cap 219 in the characteristic process will be described.

Hereinafter, the characteristic process of the substrate processing method according to the fifth embodiment will be described. In the fifth embodiment, the characteristic process is performed in the boat unloading process of unloading the boat 217 from the processing chamber 201 after the film forming is completed.

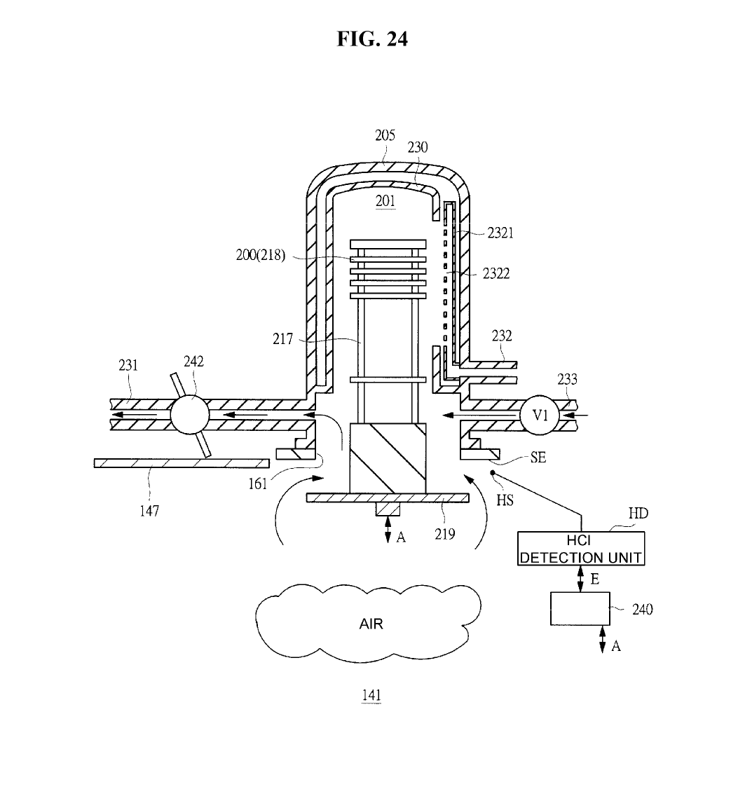

FIG. 24 is a diagram illustrating a state after the film-forming process. In FIG. 24, in the film-forming process, SiH₂Cl₂ (dichlorosilane) serving as a source gas is pyrolized and polymerized, so that a by-product such as a chlorosilane polymer is produced. The produced chlorosilane polymer is adhered to and deposited on the inside of the processing chamber 201 and the inner wall of a gas exhaust pipe 231 that is an exhaust line.

Subsequently, in the fifth embodiment, as illustrated in FIG. 24, after the film-forming process is completed, first, a valve V1 is opened by the control of the controller 240, thereby introducing air into the processing chamber 201 through an air supply pipe 233. Further, an APC valve 242 is opened by the control of the controller 240, thereby exhausting an atmosphere in the processing chamber 201 through a gas exhaust pipe 231. Thereby, in the fifth embodiment, a unidirectional flow of the air can be formed in the order of the air supply pipe 233, the inside of the processing chamber 201, and the gas exhaust pipe 231.

Further, in the fifth embodiment, a flow of the air is formed in the order of the air supply pipe 233, the inside of the processing chamber 201, and the gas exhaust pipe 231, and the flow of the air is also formed in the order of the load lock chamber 141, the gap between the seal surface SE and the seal cap 219, the inside of the processing chamber 201, and the gas exhaust pipe 231. That is, in the fifth embodiment, the seal cap 219 on which the boat 217 is held is displaced and held to a position where it is slightly separated from the seal surface SE of a furnace port 161. That is, the seal cap 219 on which the boat 217 is held is lowered and held at a position where it slightly moves down from the seal surface SE of the furnace port 161. Thereby, a gap is formed between the seal surface SE of the furnace port 161 and the seal cap 219, and the air is mixed into the processing chamber 201 through the gap. With the configuration as described above, in the fifth embodiment, the air is introduced into the processing chamber 201 through the air supply pipe 233, and the air is introduced from the load lock chamber 141 into the processing chamber 201 via the gap between the seal surface SE of the furnace port 161 and the seal cap 219.

Here, both the air that flows from the load lock chamber 141 into the processing chamber 201 via the open furnace port 161 and the air that flows into the processing chamber 201 through the air supply pipe 233 are subjected to a hydrolytic reaction with a chlorosilane polymer adhered to the inside of the processing chamber 201. Thereby, the chlorosilane polymer is changed into a high-combustible hydrolysate, and hydrogen chloride gas is generated. In the fifth embodiment, since the flow of the air having the order of the load lock chamber 141, the processing chamber 201, and the gas exhaust pipe 231 and the flow of the air having the order of the load lock chamber 141, the gap between the seal surface SE and the seal cap 219, the inside of the processing chamber 201, and the gas exhaust pipe 231 are formed, the hydrogen chloride gas generated from the inside of the processing chamber 201 hardly flows back to the load lock chamber 141, and is discharged to an outside through the gas exhaust pipe 231. Thus, according to the fifth embodiment, since the hydrogen chloride gas generated from the inside of the processing chamber 201 can be prevented from flowing back to the load lock chamber 141 through the furnace port 161, the corrosion of the furnace port 161 itself and the corrosion of the load lock chamber 141, both of which are caused by the hydrogen chloride gas, cam be prevented.

In the fifth embodiment, the high-combustible hydrolysate is also formed from the chlorosilane polymer. However, in the fifth embodiment, the flow of the air having the order of the load lock chamber 141, the processing chamber 201, and the gas exhaust pipe 231 and the flow of the air having the order of the load lock chamber 141, the gap between the seal surface SE and the seal cap 219, the inside of the processing chamber 201, and the gas exhaust pipe 231 continue to be formed. For this reason, moisture contained in the air continues to react with the chlorosilane polymer adhered to the inside of the processing chamber 201, so that the chlorosilane polymer is changed into siloxane that is a stable material. That is, in the fifth embodiment, the deposited chlorosilane polymer continues to positively react with the air, so that the chlorosilane polymer is changed into, not the high-combustible hydrolysate that is an intermediate product, but the siloxane that is a final product and a stable material. As a result, according to the fifth embodiment, the high-combustible hydrolysate can be prevented from being deposited in the processing chamber 201. Thus, according to the fifth embodiment, a problem that the high-combustible hydrolysate is abruptly burnt by impact or static electricity during the maintenance can be overcome.

Further, in the fifth embodiment, a sensor HS configured to detect the hydrogen chloride gas and an HCl detection unit HD are installed. Thereby, the hydrogen chloride gas is configured to continue to be exhausted through the gas exhaust pipe 231 until a concentration level of the hydrogen chloride gas reaches or is lower than a preset concentration level (e.g., 2 ppm). For this reason, the concentration level of the hydrogen chloride gas in the processing chamber 201 can be reliably set to be equal to or lower than a preset concentration level, and to improve safety.

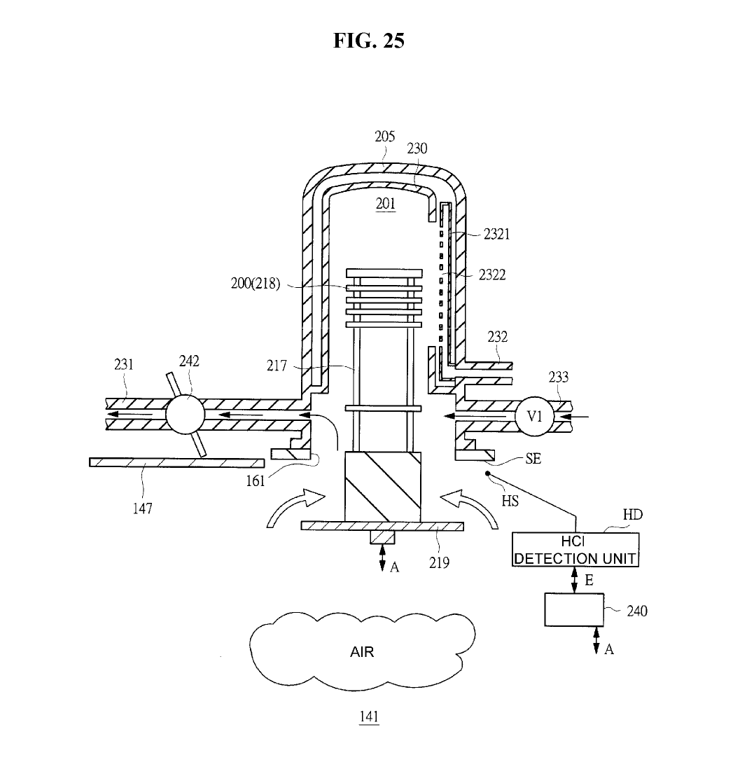

At this time, in the fifth embodiment, for example, the controller 240 sets a preset time t0, and monitors whether or not a concentration level of the hydrogen chloride gas reaches the preset concentration level within the preset time t0. When the concentration level of the hydrogen chloride gas does not reach the preset concentration level within the preset time t0, the controller 240 controls a position of the seal gap 219 so as to be further lowered and held, as illustrated in FIG. 25. As a result, the gap between the seal surface SE of the furnace port 161 and the seal cap 219 may be increased, so that an amount of the air supplied into the processing chamber 201 can be increased. Thereby, a hydrolytic reaction of the moisture contained in the air with the chlorosilane polymer adhered to the inside of the processing chamber 201 can be efficiently advanced, and the efficiency of generation of the hydrogen chloride gas can be enhanced. Thus, a great deal of hydrogen chloride gas may be generated and exhausted within a short time. As such, a time that is required until the concentration level of the hydrogen chloride gas reaches the preset concentration level can be shortened.

### Sixth Embodiment

In the sixth embodiment, an example of changing an exhaust velocity at which an atmosphere in a processing chamber 201 is exhausted through a gas exhaust pipe 231 in a characteristic process will be described.

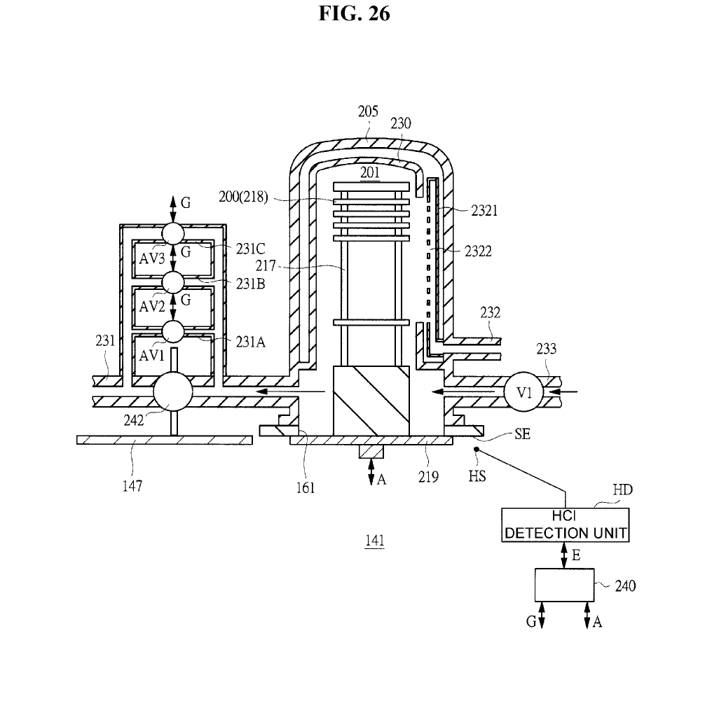

FIG. 26 is a diagram illustrating a configuration of the surroundings of the processing chamber 201 of the substrate processing apparatus according to the sixth embodiment. Since the configuration of the substrate processing apparatus according to the sixth embodiment illustrated in FIG. 26 is nearly the same as the configuration of the substrate processing apparatus according to the third embodiment illustrated in FIG. 15, a difference between the sixth embodiment and the third embodiment will be described in detail.

As can be seen from the comparison of FIG. 15 with FIG. 26, in the substrate processing apparatus according to the sixth embodiment, a bypass line is installed on the gas exhaust pipe 231 connected to the processing chamber 201. For example, as illustrated in FIG. 26, the bypass line is made up of a gas exhaust pipe 231A, a gas exhaust pipe 231B, and a gas exhaust pipe 231C. The gas exhaust pipes 231A, 231B and 231C are connected in parallel to one another. Here, the gas exhaust pipes 231A, 231B and 231C have a relationship of a diameter of the gas exhaust pipe 231A<a diameter of the gas exhaust pipe 231B<a diameter of the gas exhaust pipe 231C. Thus, an exhaust velocity caused by the gas exhaust pipe 231A is lower than that caused by the gas exhaust pipe 231B, and an exhaust velocity caused by the gas exhaust pipe 231B is lower than that caused by the gas exhaust pipe 231C. For example, the exhaust velocity caused by the gas exhaust pipe 231A is 3 liter/minute (L/min), and the exhaust velocity caused by the gas exhaust pipe 231B is 5 L/min. Further, the exhaust velocity caused by the gas exhaust pipe 231B is 10 L/min.

A valve AV1 is installed on the gas exhaust pipe 231A. The valve AV1 is configured to be opened and closed by control of a controller 240. Similarly, a valve AV2 is installed on the gas exhaust pipe 231B, and is configured to be opened and closed by control of a controller 240. Further, a valve AV3 is installed on the gas exhaust pipe 231C, and is configured to be opened and closed by control of a controller 240.

Hereinafter, the characteristic process of the substrate processing method according to the sixth embodiment will be described. In the sixth embodiment, the characteristic process is performed in the boat unloading process of unloading the boat 217 from the processing chamber 201 after the film forming is completed.

FIG. 26 is a diagram illustrating a state after the film-forming process. In FIG. 26, in the film-forming process, SiH₂Cl₂ (dichlorosilane) serving as a source gas is pyrolized and polymerized, so that a by-product such as a chlorosilane polymer is produced. The produced chlorosilane polymer is adhered to and deposited on the inside of the processing chamber 201 and an inner wall of the gas exhaust pipe 231 that is an exhaust line.

Subsequently, in the sixth embodiment, as illustrated in FIG. 26, after the film-forming process is completed, first, a valve V1 is opened by the control of the controller 240, thereby introducing air into the processing chamber 201 through an air supply pipe 233. An exhaust velocity at which the exhaust is performed through the exhaust line is adjusted by the control of the controller 240. In detail, for example, when the valve AV1 is opened by the controller 240, and when the valves AV2 and AV3 are closed by the controller 240, the atmosphere in the processing chamber 201 is exhausted through the gas exhaust pipe 231A. When the valve AV2 is opened by the controller 240, and when the valves AV1 and AV3 are closed by the controller 240, the atmosphere in the processing chamber 201 is exhausted through the gas exhaust pipe 231B. Further, when the valve AV3 is opened by the controller 240, and when the valves AV1 and AV2 are closed by the controller 240, the atmosphere in the processing chamber 201 is exhausted through the gas exhaust pipe 231C. With the configuration as described above, according to the sixth embodiment, the exhaust velocity can be adjusted using the exhaust line. At this time, in the sixth embodiment, a unidirectional flow of the air can be formed in the order of the air supply pipe 233, the inside of the processing chamber 201, and the exhaust line (the gas exhaust pipe 231A, the gas exhaust pipe 231B, or the gas exhaust pipe 231C).

Here, the air, which flows into the processing chamber 201 through the air supply pipe 233, is subjected to a hydrolytic reaction with a chlorosilane polymer adhered to the inside of the processing chamber 201. Thereby, the chlorosilane polymer is changed into a high-combustible hydrolysate, and hydrogen chloride gas is generated. In the sixth embodiment, since the unidirectional flow having the order of the air supply pipe 233, the processing chamber 201, and the exhaust line (the gas exhaust pipe 231A, the gas exhaust pipe 231B, or the gas exhaust pipe 231C) is formed, the hydrogen chloride gas generated from the inside of the processing chamber 201 is discharged to an outside through the gas exhaust pipe 231. Thus, according to the sixth embodiment, since the hydrogen chloride gas generated from the inside of the processing chamber 201 can be prevented from flowing back to the load lock chamber 141, the corrosion of the load lock chamber 141 which is caused by the hydrogen chloride gas can be effectively prevented.

In the sixth embodiment, the high-combustible hydrolysate is also formed from the chlorosilane polymer. However, in the sixth embodiment, the unidirectional flow of the air continues to be formed in the order of the air supply pipe 233, the inside of the processing chamber 201, and the exhaust line (the gas exhaust pipe 231A, the gas exhaust pipe 231B, or the gas exhaust pipe 231C). For this reason, moisture contained in the air continues to react with the chlorosilane polymer adhered to the inside of the processing chamber 201, so that the chlorosilane polymer is changed into siloxane that is a stable material. That is, in the sixth embodiment, the deposited chlorosilane polymer continues to positively react with the air, so that the chlorosilane polymer is changed into, not the high-combustible hydrolysate that is an intermediate product, but the siloxane that is a final product and a stable material. As a result, according to the sixth embodiment, the high-combustible hydrolysate can be prevented from being deposited in the processing chamber 201. Thus, according to the sixth embodiment, a problem that the high-combustible hydrolysate is abruptly burnt by impact or static electricity during the maintenance can be overcome.

Further, in the sixth embodiment, a sensor HS configured to detect the hydrogen chloride gas and an HCl detection unit HD are installed. Thereby, the hydrogen chloride gas is configured to continue to be exhausted through the gas exhaust pipe 231 until a concentration level of the hydrogen chloride gas reaches or is lower than a preset concentration level (e.g., 2 ppm). For this reason, the concentration level of the hydrogen chloride gas in the processing chamber 201 can be reliably set to be equal to or lower than a preset concentration level, and to improve safety.

According to the sixth embodiment, the exhaust velocity may be adjusted using the exhaust line. For example, when the exhaust is performed through the gas exhaust pipe 231A having a low exhaust velocity, the air introduced through the air supply pipe 233 is allowed to stay in the processing chamber 201 for a long time. As such, the moisture contained in the air is allowed to positively react with the chlorosilane polymer adhered to the inside of the processing chamber 201. Further, when the exhaust is performed through the gas exhaust pipe 231C having a high exhaust velocity, the air introduced through the air supply pipe 233 is allowed to positively flow through the exhaust line. As such, the moisture contained in the air is allowed to react with the chlorosilane polymer adhered to the exhaust line. That is, according to the sixth embodiment, when the moisture contained in the air is first caused to react with the chlorosilane polymer adhered to the inside of the processing chamber 201, the exhaust can be controlled so as to be performed through the gas exhaust pipe 231A having the low exhaust velocity, whereas, when the moisture contained in the air is first caused to react with the chlorosilane polymer adhered to the inner wall of the exhaust line, the exhaust can be controlled so as to be performed through the gas exhaust pipe 231C having the high exhaust velocity.

As a concrete example, the exhaust velocity can be controlled when the characteristic process (air introducing process) is terminated so as to be higher than the exhaust velocity when the characteristic process (air introducing process) is initiated. Thereby, in the step of initiating the characteristic process, the chlorosilane polymer adhered to the inside of the processing chamber 201 can be removed (cleaned). In the step of terminating the characteristic process or terminating the cleaning of the processing chamber 201, the chlorosilane polymer adhered to the exhaust line first can be removed (cleaned).

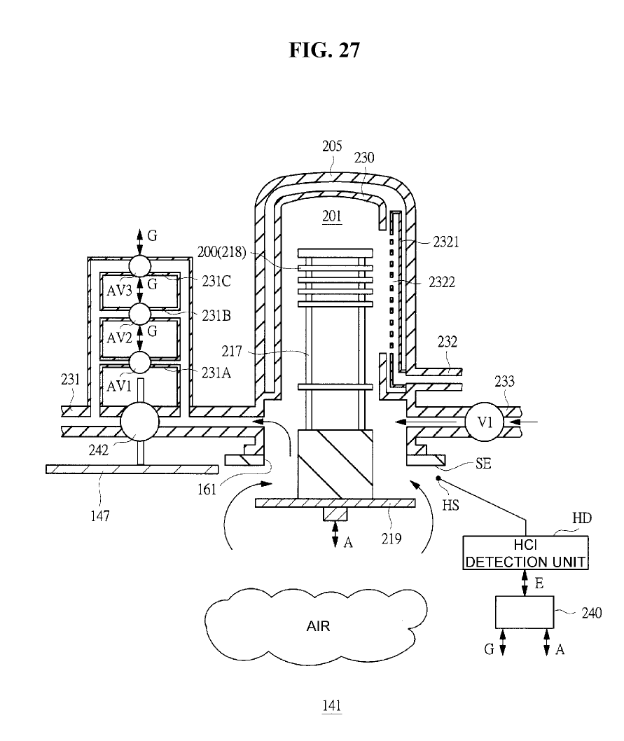

Further, as illustrated in FIG. 26, the characteristic process in the sixth embodiment may be performed, for instance, in the boat unloading process of unloading the boat 217 from the processing chamber after the film forming is completed. However, the characteristic process in the boat unloading process may be performed, for instance, as illustrated in FIG. 27.

In the example illustrated in FIG. 27, a flow of the air is formed in the order of the air supply pipe 233, the inside of the processing chamber 201, and the exhaust line (the gas exhaust pipe 231A, the gas exhaust pipe 231B, or the gas exhaust pipe 231C), and the flow of the air is also formed in the order of the load lock chamber 141, the gap between the seal surface SE and the seal cap 219, the inside of the processing chamber 201, and the exhaust line (the gas exhaust pipe 231A, the gas exhaust pipe 231B, or the gas exhaust pipe 231C). That is, in the example illustrated in FIG. 27, the air is introduced into the processing chamber 201 through the air supply pipe 233, and the air is also introduced from the load lock chamber 141 into the processing chamber 201 via the gap between the seal surface SE and the seal cap 219. Thereby, an amount of supply of the air introduced into the processing chamber 201 can be increased.

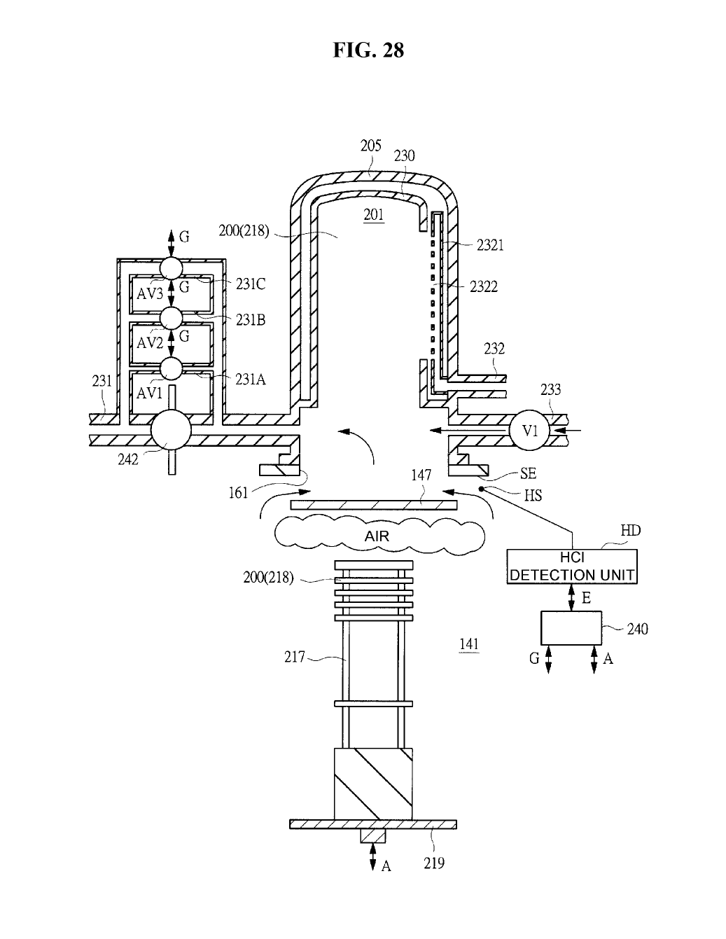

Further, as illustrated in FIG. 28, the characteristic process in the sixth embodiment may be performed, for instance, in a standby process of charging a new wafer into the boat aside from the wafer 200 undergoing the film forming after the boat unloading process is performed immediately after the film-forming process.

In the example illustrated in FIG. 28, a flow of the air is formed in the order of the air supply pipe 233, the inside of the processing chamber 201, and the exhaust line (the gas exhaust pipe 231A, the gas exhaust pipe 231B, or the gas exhaust pipe 231C), and the flow of the air is also formed in the order of the load lock chamber 141, the gap between the seal surface SE and the furnace port shutter 147, the inside of the processing chamber 201, and the exhaust line (the gas exhaust pipe 231A, the gas exhaust pipe 231B, or the gas exhaust pipe 231C). That is, in the example illustrated in FIG. 28, the air is introduced into the processing chamber 201 through the air supply pipe 233, and the air is also introduced from the load lock chamber 141 into the processing chamber 201 via the gap between the seal surface SE and the furnace port shutter 147. Thereby, an amount of supply of the air introduced into the processing chamber 201 can be increased.

Further, the characteristic process in the sixth embodiment may be performed in the boat loading process performed after the standby process.

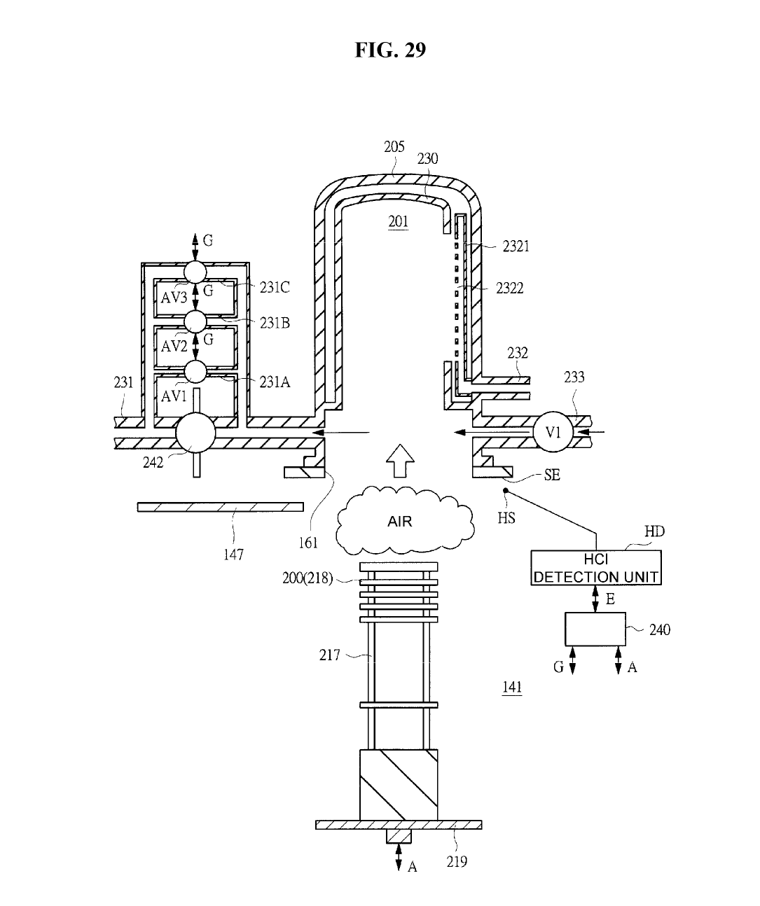

In the example illustrated in FIG. 29, a flow of the air is formed in the order of the air supply pipe 233, the inside of the processing chamber 201, and the exhaust line (the gas exhaust pipe 231A, the gas exhaust pipe 231B, or the gas exhaust pipe 231C), and the flow of the air is also formed in the order of the load lock chamber 141, the open furnace port 161, the inside of the processing chamber 201, and the exhaust line (the gas exhaust pipe 231A, the gas exhaust pipe 231B, or the gas exhaust pipe 231C). That is, in the example illustrated in FIG. 29, the air is introduced into the processing chamber 201 through the air supply pipe 233, and the air is also introduced from the load lock chamber 141 into the processing chamber 201 via the open furnace port 161. Thereby, an amount of supply of the air introduced into the processing chamber 201 can be increased.

While the prevent invention made by the inventors has been described above in detail based on the embodiments thereof, the prevent invention is not limited to these embodiments. It is apparent that various modifications and changes can be made within the scope of the prevent invention without departing from the subject matter of the present invention.

The conditions of forming the semiconductor film described in the embodiments are nothing but one example, and the conditions can be properly changed. For example, when the semiconductor film is formed by a chemical vapor deposition (CVD) method, silicon tetrachloride (SiCl₄) may be used as a source gas, and diboran (B₂H) that is a boron-containing gas may be used as a dopant gas. Further, hydrogen (H₂) may be used as a carrier gas.

In the embodiments, the example of supplying the air through the air supply pipe 233 has been described. Instead of the air, a gas that at least contains moisture (H₂O) or can produce the moisture in the processing chamber 201, such as water vapor (H₂O), hydrogen (H₂) gas+oxygen (O₂) gas, or the like, may be supplied.

Further, in the embodiments, with respect to the high-combustible hydrolysate serving as the by-product deposited on the inside of the processing chamber 201 and the exhaust line when the wafer 200 is processed, the example of supplying the moisture into the processing chamber 201, and positively generating the high-corrosive gas from the hydrolysate has been described, but the invention is not limited to this example. For example, with respect to the adherent adhered to the inside of the processing chamber 201 and the exhaust line when the film-forming gas is supplied to process the wafer 200, the reactive gases reacting with the adherent may be supplied into the processing chamber 201, and be exhausted through the exhaust line, and the gas produced from the adherent adhered to the inside of the processing chamber 201 and the exhaust line may be positively generated. In this case, the HCl detection unit HD may be configured as a generated gas detection unit.

Further, in the specification, the example of applying the technical idea of the invention to the substrate processing chamber having an induction heating system has been described. The technical idea of the invention is not limited to this application. For example, the technical idea of the invention may be applied to a substrate processing apparatus having a resistance heating system. In the case of the substrate processing apparatus having a resistance heating system, for example, the wafer 200 is directly placed on the boat without installation of the susceptor 218, and the induction heating unit 206 is replaced with a resistance heating unit.

The present invention includes at least the following embodiments.

### (Supplementary Note 1)

A substrate processing method including:

(a) forming a film on a substrate in a processing chamber; and

(b) introducing an air from an outside of the processing chamber into an inside of the processing chamber, reacting an adherent adhered to the inside of the processing chamber and an inside of an exhaust line connected to the processing chamber with a moisture contained in the air to generate at least a hydrogen chloride gas, and exhausting the hydrogen chloride gas through the exhaust line,

wherein the step (b) is performed after performing the step (a) and the step (b) is performed until a concentration level of the hydrogen chloride gas in the processing chamber is equal to or lower than a preset concentration level.

### (Supplementary Note 2)

In the method of Supplementary Note 1, wherein the step (b) is performed in an unloading step in which the substrate having the film formed thereon is unloaded from the processing chamber or in a loading step wherein a separate substrate other than the substrate having the film formed thereon is loaded into the processing chamber after the unloading step.

### (Supplementary Note 3)

In the method of Supplementary Note 1, wherein the step (b) is performed in an unloading step in which the substrate having the film formed thereon is unloaded from the processing chamber.

### (Supplementary Note 4)

In the method of Supplementary Note 1, wherein the air is introduced into the inside of the processing chamber by an air supply unit installed in the processing chamber.

### (Supplementary Note 5)

In the method of Supplementary Note 4, wherein the air supply unit includes an opening of the processing chamber wherethrough the substrate is loaded and unloaded.

### (Supplementary Note 6)

In the method of Supplementary Note 4, wherein the air supply unit includes an air supply line connected to the processing chamber and a valve connected to the air supply line, and introduces the air into the processing chamber by opening the valve.

### (Supplementary Note 7)

In the method of Supplementary Note 1, wherein, in the step (b), the concentration level of the hydrogen chloride gas in the processing chamber is monitored, and an amount of the air introduced into the inside of the process chamber is increased when the concentration level of the hydrogen chloride gas exceeds the preset concentration level within a preset time.

### (Supplementary Note 8)

In the method of Supplementary Note 7, wherein, in the step (b), an inert gas is continuously supplied into the processing chamber from a processing gas supply unit supplying a processing gas, and an amount of the inert gas supplied into the processing chamber is decreased when the concentration level of the hydrogen chloride gas exceeds the preset concentration level within the preset time.

### (Supplementary Note 9)

In the method of Supplementary Note 7, wherein, in the step (b), an opening degree of an opening of the processing chamber wherethrough the substrate is loaded and unloaded is increased when the concentration level of the hydrogen chloride gas exceeds the preset concentration level within the preset time.

### (Supplementary Note 10)

In the method of Supplementary Note 1, wherein, in the step (b), an exhaust velocity whereby the hydrogen chloride gas is exhausted through the exhaust line is varied.

### (Supplementary Note 11)

In the method of Supplementary Note 10, wherein, in the step (b), the exhaust velocity is higher at an end of the step (b) than at a start of the step (b).

### (Supplementary Note 12)

In the method of Supplementary Note 1, wherein the step (b) is performed at every completion of the step (a).

### (Supplementary Note 13)

In the method of Supplementary Note 1, wherein the step (b) is performed in an unloading step in which the substrate having the film formed thereon is unloaded from the processing chamber and in a loading step in which a different substrate other than the substrate having the film formed thereon is loaded into the processing chamber after the unloading step in a manner that a time for introducing the air from the outside of the processing chamber into the inside of the processing chamber in the unloading step is longer than a time for introducing the air from the outside of the processing chamber into the inside of the processing chamber in the loading step.

### (Supplementary Note 14)

A substrate processing method including:

(a) supplying a film-forming gas into a processing chamber, and exhausting the film-forming gas through an exhaust line to form a film on the substrate; and

(b) supplying into the processing chamber a reactive gas reactive with an adherent adhered to an inside of the processing chamber and an inside of the exhaust line and exhausting the reactive gas through the exhaust line to generate a product gas from the adherent, and exhausting the product gas through the exhaust line,

wherein the step (b) is performed until a concentration level of the product gas in the processing chamber is equal to or lower than a preset concentration level.

### (Supplementary Note 15)

A substrate processing apparatus including:

a processing chamber configured to process a substrate;

a gas supply unit configured to supply a film-forming gas into the processing chamber;

an opening configured to introduce an air into the processing chamber;

an exhaust line connected to the processing chamber to exhaust an atmosphere of the processing chamber; and

a control unit configured to control the gas supply unit so as to supply the film-forming gas, the exhaust line so as to exhaust the atmosphere of the processing chamber and the opening so as to introduce the air,

wherein the control unit controls the gas supply unit to form a film on the substrate in the processing chamber, and controls the opening and the exhaust line to introduce an air into an inside of the processing chamber through the opening; to react an adherent adhered to the inside of the processing chamber and an inside of an exhaust line with a moisture contained in the air to generate at least a hydrogen chloride gas; and to exhaust the hydrogen chloride gas through the exhaust line until a concentration level of the hydrogen chloride gas in the processing chamber is equal to or lower than a preset concentration level.

Among the inventions disclosed herein, the effects obtained from the typical invention will be briefly described as follows.

The substrate processing apparatus and method that are capable of preventing deposition of a reactive product to the inside of a processing chamber and an exhaust line, increasing maintainability or safety, and preventing the corrosion of the surroundings of the processing chamber may be provided.

What is claimed is:

1. A substrate processing method, comprising:
(a) forming a film on a substrate in a processing chamber; and
(b) introducing an air from an outside of the processing chamber into an inside of the processing chamber, reacting an adherent adhered to the inside of the processing chamber and an inside of an exhaust line connected to the processing chamber with a moisture contained in the air to generate at least a hydrogen chloride gas, and exhausting the hydrogen chloride gas through the exhaust line,
wherein the step (b) is performed after performing the step (a) and the step (b) is performed until a concentration level of the hydrogen chloride gas in the processing chamber is equal to or lower than a preset concentration level.

2. The method of claim 1, wherein the step (b) is performed in an unloading step wherein the substrate having the film formed thereon is unloaded from the processing chamber or in a loading step in which a different substrate other than the substrate having the film formed thereon is loaded into the processing chamber after the unloading step.

3. The method of claim 1, wherein the step (b) is performed in an unloading step in which the substrate having the film formed thereon is unloaded from the processing chamber.

4. The method of claim 1, wherein the air is introduced into the inside of the processing chamber by an air supply unit installed in the processing chamber.

5. The method of claim 4, wherein the air supply unit includes an opening of the processing chamber wherethrough the substrate is loaded and unloaded.

6. The method of claim 4, wherein the air supply unit includes an air supply line connected to the processing chamber and a valve connected to the air supply line, and introduces the air into the processing chamber by opening the valve.

7. The method of claim 1, wherein, in the step (b), the concentration level of the hydrogen chloride gas in the processing chamber is monitored, and an amount of the air introduced into the inside of the process chamber is increased when the concentration level of the hydrogen chloride gas exceeds the preset concentration level within a preset time.

8. The method of claim 7, wherein, in the step (b), an inert gas is continuously supplied into the processing chamber from a processing gas supply unit supplying a processing gas, and an amount of the inert gas supplied into the processing chamber is decreased when the concentration level of the hydrogen chloride gas exceeds the preset concentration level within the preset time.

9. The method of claim 7, wherein, in the step (b), an opening degree of an opening of the processing chamber wherethrough the substrate is loaded and unloaded is increased when the concentration level of the hydrogen chloride gas exceeds the preset concentration level within the preset time.

10. The method of claim 1, wherein, in the step (b), an exhaust velocity whereby the hydrogen chloride gas is exhausted through the exhaust line is varied.

11. The method of claim 10, wherein, in the step (b), the exhaust velocity is higher at an end of the step (b) than at a start of the step (b).

12. The method of claim 1, wherein the step (b) is performed at every completion of the step (a).

13. The method of claim 1, wherein the step (b) is performed in an unloading step in which the substrate having the film formed thereon is unloaded from the processing chamber and in a loading step in which a different substrate other than the substrate having the film formed thereon is loaded into the processing chamber after the unloading step in a manner that a time for introducing the air from the outside of the processing chamber into the inside of the processing chamber in the unloading step is longer than a time for introducing the air from the outside of the processing chamber into the inside of the processing chamber in the loading step.

14. A substrate processing method, comprising:
(a) supplying a film-forming gas into a processing chamber, and exhausting the film-forming gas through an exhaust line to form a film on the substrate; and
(b) supplying into the processing chamber a reactive gas reactive with an adherent adhered to an inside of the processing chamber and an inside of the exhaust line and exhausting the reactive gas through the exhaust line to generate a product gas from the adherent, and exhausting the product gas through the exhaust line,
wherein the step (b) is performed until a concentration level of the product gas in the processing chamber is equal to or lower than a preset concentration level.

15. A substrate processing apparatus comprising:
a processing chamber configured to process a substrate;
a gas supply unit configured to supply a film-forming gas into the processing chamber;
an opening configured to introduce an air into the processing chamber;
an exhaust line connected to the processing chamber to exhaust an atmosphere of the processing chamber; and
a control unit configured to control the gas supply unit so as to supply the film-forming gas, the exhaust line so as to exhaust the atmosphere of the processing chamber, and the opening so as to introduce the air,
wherein the control unit controls the gas supply unit to form a film on the substrate in the processing chamber, and controls the opening and the exhaust line to introduce an air into an inside of the processing chamber through an opening; to react an adherent adhered to the inside of the processing chamber and an inside of an exhaust line with a moisture contained in the air to generate at least a hydrogen chloride gas; and to exhaust the hydrogen chloride gas through the exhaust line until a concentration level of the hydrogen chloride gas in the processing chamber is equal to or lower than a preset concentration level.
